(19) United States
(12) Patent Application Publication
(10) Pub. No.: US 2024/0057464 A1
(43) Pub. Date: Feb. 15, 2024

(54) MANUFACTURING EQUIPMENT FOR LIGHT-EMITTING DEVICE

(71) Applicant: SEMICONDUCTOR ENERGY LABORATORY CO., LTD., Atsugi-shi, Kanagawa-ken (JP)

(72) Inventors: Shingo EGUCHI, Atsugi, Kanagawa (JP); Hiroki ADACHI, Tochigi, Tochigi (JP); Kenichi OKAZAKI, Atsugi, Kanagawa (JP); Yasumasa YAMANE, Atsugi, Kanagawa (JP); Naoto KUSUMOTO, Isehara, Kanagawa (JP); Kensuke YOSHIZUMI, Atsugi, Kanagawa (JP); Shunpei YAMAZAKI, Setagaya, Tokyo (JP)

(21) Appl. No.: 18/260,841

(22) PCT Filed: Jan. 7, 2022
(86) PCT No.: PCT/IB2022/050107

§ 371 Date: Jul. 10, 2023

(30) Foreign Application Priority Data
Jan. 14, 2021 (JP) 2021-004537
Jan. 28, 2021 (JP) 2021-011853

(51) Int. Cl. H10K 71/00; H01L 21/67; C23C 14/56; C23C 16/54; G03F 7/00

(52) U.S. Cl. CPC H10K 71/811; H01L 21/67167; H01L 21/67184; C23C 14/566; C23C 16/54; G03F 7/0005; H01L 21/68707

(57) ABSTRACT

Manufacturing equipment of a light-emitting device with which steps from formation to sealing of a light-emitting element can be successively performed can be provided. In the manufacturing equipment of a light-emitting device, a deposition step, a lithography step, an etching step, and a sealing step by forming a protective layer for forming an organic EL element can be successively performed, whereby a downscaled organic EL element achieving high luminance and high reliability can be formed. Moreover, the manufacturing equipment can have an in-line system where apparatuses are arranged in the order of process steps for the light-emitting device, resulting in high throughput manufacturing.

### TECHNICAL FIELD

One embodiment of the present invention relates to manufacturing equipment and a manufacturing method of a light-emitting device.

Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Accordingly, more specific examples of the technical field of one embodiment of the present invention disclosed in this specification include a semiconductor device, a display device, a liquid crystal display device, a light-emitting apparatus, a lighting device, a power storage device, a memory device, an image capturing device, an operation method thereof, and a manufacturing method thereof.

### BACKGROUND ART

In recent years, higher-resolution display panels have been required. Examples of devices that require high-resolution display panels include a smartphone, a tablet terminal, and a notebook computer. Furthermore, higher resolution has been required for a stationary display device such as a television device or a monitor device along with an increase in definition. An example of a device required to have the highest resolution is a device for virtual reality (VR) or augmented reality (AR).

Examples of a display device that can be used for a display panel include, typically, a liquid crystal display device, a light-emitting device including a light-emitting element such as an organic EL (Electro Luminescence) element or a light-emitting diode (LED), and electronic paper performing display by an electrophoretic method or the like.

For example, an organic EL element has a structure where a layer containing a light-emitting organic compound is held between a pair of electrodes. By voltage application to this element, light emission can be obtained from the light-emitting organic compound. A display device using such an organic EL element does not need a backlight that is necessary for a liquid crystal display device and the like; thus, a thin, lightweight, high-contrast, and low-power display device can be achieved. Patent Document 1, for example, discloses an example of a display device using an organic EL element.

### REFERENCE

### Patent Document

[Patent Document 1] Japanese Published Patent Application No. 2002-324673

### SUMMARY OF THE INVENTION

### Problems to be Solved by the Invention

As an organic EL display device capable of full-color display, a structure in which white-light-emitting elements and color filters are combined and a structure in which R, G, and B light-emitting elements are formed in the same plane are known.

The latter structure is ideal in terms of power consumption, and light-emitting materials are separately deposited using a metal mask or the like in manufacture of medium- and small-size panels under the existing circumstances. However, the process using a metal mask causes a problem such as low alignment accuracy and needs a reduction in an area occupied by light-emitting elements in a pixel, resulting in difficulty in increasing an aperture ratio.

Therefore, an issue of the process using a metal mask is to increase the density of pixels and emission intensity. It is preferable to increase the area of a light-emitting element with the use of a lithography step or the like for increasing the aperture ratio. However, the reliability of a material included in the light-emitting element is lowered when impurities (e.g., water, oxygen, and hydrogen) in the air enter the material, necessitating performing a plurality of steps in a controlled atmosphere.

In the case where a light-emitting device is fabricated with a vacuum evaporation method using a metal mask, an issue such as necessity of a plurality of manufacturing equipment lines arises. For example, since a metal mask has to be cleaned regularly, at least two or more manufacturing equipment lines are necessary, and one of the lines is used for device fabrication while the other equipment line is being under maintenance. In consideration of mass production, a plurality of manufacturing equipment lines are required. Thus, the issue is that the initial investment for introducing manufacturing equipment significantly increases.

Furthermore, there is a demand for small-size high-resolution displays for AR and VR. Displays for AR and VR are incorporated into devices with small volume, such as glasses-type or goggle-type devices, and accordingly preferably have narrow bezels. Therefore, drivers for a pixel circuit and the like of the displays are preferably provided below the pixel circuit.

In view of this, an object of one embodiment of the present invention is to provide manufacturing equipment of a light-emitting device with which steps from formation to sealing of a light-emitting element can be successively performed without exposure to the air. Another object is to provide manufacturing equipment of a light-emitting device with which a light-emitting element can be formed without using a metal mask. Another object is to provide a method for manufacturing a light-emitting device.

Note that the description of these objects does not preclude the existence of other objects. One embodiment of the present invention does not have to achieve all the objects. Note that other objects will be apparent from the description of the specification, the drawings, the claims, and the like, and other objects can be derived from the description of the specification, the drawings, the claims, and the like.

### Means for Solving the Problems

One embodiment of the present invention relates to manufacturing equipment and a manufacturing method of a light-emitting device.

A first embodiment of one embodiment of the present invention is manufacturing equipment of a light-emitting device, including a first cluster to an eleventh cluster and a first loadlock chamber to a tenth loadlock chamber. The first cluster is connected to the second cluster through the first loadlock chamber; the second cluster is connected to the third cluster through the second loadlock chamber: the third cluster is connected to the fourth cluster through the third loadlock chamber; the fourth cluster is connected to the fifth cluster through the fourth loadlock chamber; the fifth cluster is connected to the sixth cluster through the fifth loadlock chamber; the sixth cluster is connected to the seventh cluster through the sixth loadlock chamber; the seventh cluster is connected to the eighth cluster through the seventh loadlock chamber; the eighth cluster is connected to the ninth cluster through the eighth loadlock chamber; the ninth cluster is connected to the tenth cluster through the ninth loadlock chamber; the tenth cluster is connected to the eleventh cluster through the tenth loadlock chamber; pressures in the first cluster, the third cluster, the fourth cluster, the sixth cluster, the seventh cluster, the ninth cluster, and the eleventh cluster are controlled to reduced pressures; atmospheres in the second cluster, the fifth cluster, the eighth cluster, and the tenth cluster are controlled to inert gas atmospheres; the first cluster, the fourth cluster, and the seventh cluster each include a first carrying device and a plurality of deposition apparatuses; the third cluster, the sixth cluster, and the ninth cluster each include a second carrying device, an etching apparatus, and an ashing apparatus; the second cluster, the fifth cluster, and the eighth cluster each include a third carrying device and a plurality of apparatuses where a lithography step is performed; the tenth cluster includes a fourth carrying device and an etching apparatus; the eleventh cluster includes a fifth carrying device and a plurality of deposition apparatuses; the first carrying device includes a substrate fixing portion; and the substrate can be reversed by rotating the portion.

A second embodiment of one embodiment of the present invention is manufacturing equipment including a first cluster to an eleventh cluster and a first loadlock chamber to a tenth loadlock chamber. The first cluster is connected to the second cluster through the first loadlock chamber; the second cluster is connected to the third cluster through the second loadlock chamber; the third cluster connected to the fourth cluster through the third loadlock chamber; the fourth cluster is connected to the fifth cluster through the fourth loadlock chamber; the fifth cluster is connected to the sixth cluster through the fifth loadlock chamber; the sixth cluster is connected to the seventh cluster through the sixth loadlock chamber; the seventh cluster is connected to the eighth cluster through the seventh loadlock chamber; the eighth cluster is connected to the ninth cluster through the eighth loadlock chamber; the ninth cluster is connected to the tenth cluster through the ninth loadlock chamber; the tenth cluster is connected to the eleventh cluster through the tenth loadlock chamber; pressures in the first cluster, the third cluster, the fourth cluster, the sixth cluster, the seventh cluster, the ninth cluster, and the eleventh cluster are controlled to reduced pressures; atmospheres in the second cluster, the fifth cluster, the eighth cluster, and the tenth cluster are controlled to inert gas atmospheres; the first cluster, the fourth cluster, and the seventh cluster each include a first carrying device, a substrate transfer device, and a plurality of deposition apparatuses; the third cluster, the sixth cluster, and the ninth cluster each include a second carrying device, an etching apparatus, and an ashing apparatus; the second cluster, the fifth cluster, and the eighth cluster each include a third carrying device and a plurality of apparatuses where a lithography step is performed; the tenth cluster includes a fourth carrying device and an etching apparatus; the eleventh cluster includes a fifth carrying device and a plurality of deposition apparatuses; the substrate transfer device includes a stage, a sixth carrying device, and a seventh carrying device; a mask jig can be placed on the stage; the first carrying device is capable of carrying the mask jig where a substrate is mounted; the sixth carrying device can reverse the substrate and mount the substrate on the mask jig; and the seventh carrying device can take out the substrate mounted on the mask jig and reverse the substrate.

In the second embodiment of the present invention, the substrate transfer device can be provided with a camera, the sixth carrying device can be provided with a substrate rotation mechanism, and the substrate can be aligned with the camera and the substrate rotation mechanism and can be mounted on the mask jig.

In the second embodiment of the present invention, a plurality of substrates can be mounted on the mask jig.

The first embodiment and the second embodiment of the present invention can each include a twelfth cluster and an eleventh loadlock chamber. The twelfth cluster can be connected to the first cluster through the eleventh loadlock chamber, an atmosphere in the twelfth cluster can be controlled to an inert gas atmosphere, and the twelfth cluster can include a cleaning apparatus and a baking apparatus.

Furthermore, the twelfth cluster can include a load chamber, and the eleventh cluster can include an unload chamber.

Moreover, a thirteenth cluster, a fourteenth cluster, a twelfth loadlock chamber, and a thirteenth loadlock chamber may be included. The thirteenth cluster may be connected to the third cluster through the third loadlock chamber; the thirteenth cluster may be connected to the fourth cluster through the twelfth loadlock chamber; the fourteenth cluster may be connected to the sixth cluster through the sixth loadlock chamber; the fourteenth cluster may be connected to the seventh cluster through the thirteenth loadlock chamber; atmospheres in the thirteenth cluster and the fourteenth cluster may be controlled to inert gas atmospheres, and the thirteenth cluster and the fourteenth cluster may each include a cleaning apparatus and a baking apparatus.

The deposition apparatus is preferably one or more of an evaporation apparatus, a sputtering apparatus, a CVD apparatus, and an ALD apparatus.

The etching apparatus included in each of the third cluster, the sixth cluster, and the ninth cluster is preferably a dry etching apparatus.

The etching apparatus included in the tenth cluster is preferably a wet etching apparatus.

An application apparatus, a light-exposure apparatus, a developing apparatus, and a baking apparatus can be included as the plurality of apparatuses where the lithography step is performed. Alternatively, an application apparatus and a nanoimprint apparatus can be included as the plurality of apparatuses where the lithography step is performed.

A silicon wafer can be used as the substrate. In addition, each of the deposition apparatuses can be provided with an alignment mechanism and a mask jig, and the alignment mechanism can attach the substrate closely to the mask jig.

### Effect of the Invention

According to one embodiment of the present invention, manufacturing equipment of a light-emitting device with which steps from formation to sealing of a light-emitting element can be successively performed without exposure to the air can be provided. Alternatively, manufacturing equipment of a light-emitting device with which a light-emitting element can be formed without using a metal mask can be provided. Further alternatively, a method for manufacturing a light-emitting device can be provided.

Note that the description of these effects does not preclude the existence of other effects. One embodiment of the present invention does not need to have all of these effects. Note that effects other than these can be derived from the descriptions of the specification, the drawings, the claims, and the like.

### BRIEF DESCRIPTION OF THE DRAWINGS

FIG. 1 is a block diagram illustrating manufacturing equipment.

FIG. 2 is a diagram illustrating manufacturing equipment.

FIG. 3 is a diagram illustrating manufacturing equipment.

FIG. 4 is a diagram illustrating manufacturing equipment.

FIG. 5 is a diagram illustrating manufacturing equipment.

FIG. 6 is a block diagram illustrating manufacturing equipment.

FIG. 7 is a diagram illustrating manufacturing equipment.

FIG. 8 is a diagram illustrating manufacturing equipment.

FIG. 9 is a block diagram illustrating manufacturing equipment.

FIG. 10 is a diagram illustrating manufacturing equipment.

FIG. 11 is a diagram illustrating manufacturing equipment.

FIG. 12A to FIG. 12C are diagrams illustrating carrying a substrate.

FIG. 13A to FIG. 13C are diagrams illustrating carrying a substrate.

FIG. 14A is a diagram illustrating a vacuum process apparatus. FIG. 14B is a diagram illustrating carry-in of a substrate into the vacuum process apparatus.

FIG. 15A to FIG. 15C each illustrate an example of the number of display devices obtained from one substrate.

FIG. 16 is a block diagram illustrating manufacturing equipment.

FIG. 17 is a diagram illustrating manufacturing equipment.

FIG. 18 is a diagram illustrating manufacturing equipment.

FIG. 19 is a diagram illustrating manufacturing equipment.

FIG. 20 is a diagram illustrating manufacturing equipment.

FIG. 21 is a block diagram illustrating manufacturing equipment.

FIG. 22 is a diagram illustrating manufacturing equipment.

FIG. 23 is a diagram illustrating manufacturing equipment.

FIG. 24A to FIG. 24C are diagrams illustrating carrying a substrate.

FIG. 25A to FIG. 25C are diagrams illustrating carrying a substrate.

FIG. 26A and FIG. 26B are diagrams illustrating carrying a substrate.

FIG. 27A is a diagram illustrating cross-sections of a carrying device and a mask jig. FIG. 27B is a diagram illustrating the cross-section of the mask jig. FIG. 27C and FIG. 27D are diagrams each illustrating a mask jig.

FIG. 28A is a diagram illustrating a vacuum process apparatus. FIG. 28B is a diagram illustrating a cooling plate. FIG. 28C is a diagram illustrating a cross-section of the cooling plate.

FIG. 29 is a diagram illustrating a display device.

FIG. 30A to FIG. 30C are diagrams illustrating display devices.

FIG. 31A to FIG. 31D are diagrams illustrating a manufacturing method of a display device.

FIG. 32A to FIG. 32D are diagrams illustrating a manufacturing method of a display device.

FIG. 33A to FIG. 33E are diagrams illustrating an example of a method for manufacturing a display device.

FIG. 34 is a diagram illustrating manufacturing equipment.

FIG. 35 is a diagram illustrating manufacturing equipment.

### MODE FOR CARRYING OUT THE INVENTION

Embodiments are described in detail with reference to the drawings. Note that the present invention is not limited to the following description, and it will be readily understood by those skilled in the art that modes and details of the present invention can be modified in various ways without departing from the spirit and scope of the present invention. Therefore, the present invention should not be construed as being limited to the description of embodiments below. Note that in structures of the invention described below, the same reference numerals are used in common, in different drawings, for the same portions or portions having similar functions, and a repeated description thereof is omitted in some cases. Note that the hatching of the same component that constitutes a drawing is sometimes omitted or changed as appropriate in different drawings.

### Embodiment 1

In this embodiment, manufacturing equipment of a light-emitting device that is one embodiment of the present invention is described with reference to drawings.

One embodiment of the present invention is manufacturing equipment mainly used for formation of a display device including a light-emitting element (also referred to as a light-emitting device) such as an organic EL element. It is preferable to use a lithography step in order to downscale the organic EL element or to increase the area occupied by the organic EL element in a pixel. However, the reliability is impaired when impurities such as water, oxygen, and hydrogen enter the organic EL element. Therefore, in order not to expose top surfaces and side surfaces of patterned organic compound layers to the air, some ingenuity is necessary; for example, the atmosphere needs to be controlled to have a low dew point from the manufacturing stage.

With the manufacturing equipment of one embodiment of the present invention, a deposition step, a lithography step, an etching step, and a sealing step for forming an organic EL element can be successively performed without exposure to the air. Accordingly, a downscaled organic EL element achieving high luminance and high reliability can be formed. Moreover, the manufacturing equipment of one embodiment of the present invention can have an in-line system where apparatuses are arranged in the order of process steps for the light-emitting device, resulting in high throughput manufacturing.

As a supporting substrate for forming an organic EL element, a silicon wafer can be used. A silicon wafer where a driver circuit, a pixel circuit, and the like are formed in advance is used as a support substrate, and an organic EL element can be formed over these circuits. Thus, a display device with a narrow bezel, which is suitable for AR or VR, can be formed. The silicon wafer is preferably ϕ8 inches or more (e.g., ϕ12 inches).

### Structure Example 1

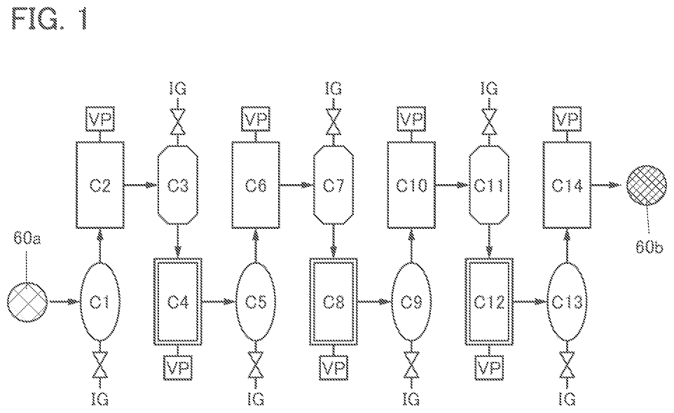

FIG. 1 is a block diagram illustrating the manufacturing equipment of a light-emitting device that is one embodiment of the present invention. The manufacturing equipment includes a plurality of clusters arranged in the order of process steps. In this specification, a group of apparatuses which shares a carrying device or the like is called a cluster. A substrate where light-emitting devices are formed is moved between the clusters in sequence, so that the steps are conducted.

The manufacturing equipment illustrated in FIG. 1 is an example including a cluster C1 to a cluster C14. The clusters C1 to C14 are sequentially connected. A substrate 60a taken into the cluster C1 can be taken out, from the cluster C14, as a substrate 60b where a light-emitting device is formed.

The clusters C1, C3, C5, C7, C9, C11, and C13 each include a group of apparatuses for performing a process under atmosphere control. The clusters C2, C4, C6, C10, C12, and C14 each include a group of apparatuses for performing vacuum processing (process under reduced pressure).

The clusters C1, C5, and C9 include apparatuses mainly for cleaning and baking the substrate, and the like. The clusters C2, C6, and C10 each include apparatuses mainly for forming an organic compound included in the light-emitting device and the like. The clusters C3, C7, and C11 each include apparatuses mainly for performing a lithography step, and the like. The clusters C4, C8, and C12 each include apparatuses mainly for performing an etching step and an ashing step, and the like. The cluster C13 includes apparatuses for an etching step and cleaning the substrate, and the like. The cluster C14 includes apparatuses mainly for forming an organic compound included in the light-emitting device and forming a protective film to seal the light-emitting device, and the like.

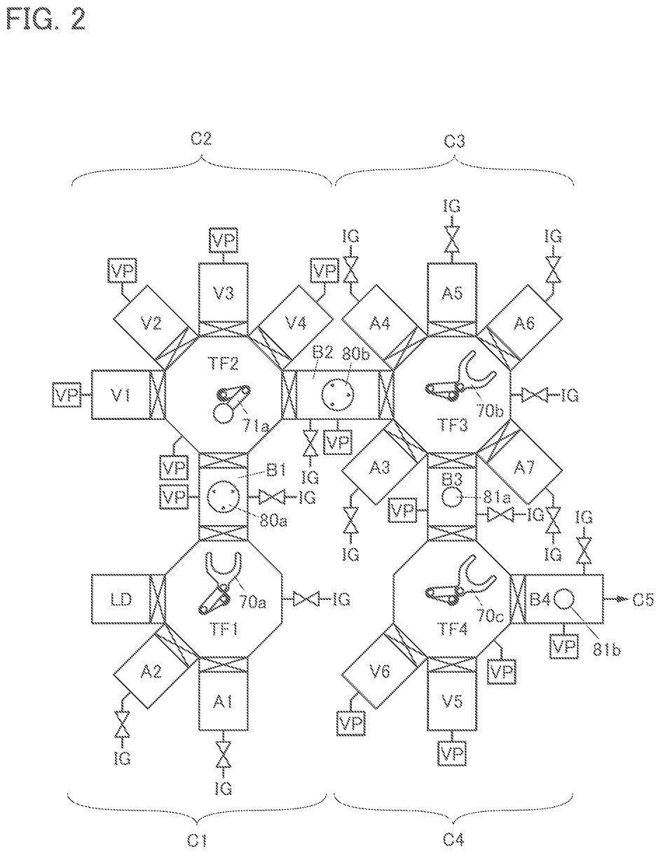

Next, the cluster C1 to the cluster C14 are described in detail with reference to FIG. 2 to FIG. 5.

### <Cluster C1 to Cluster C4>

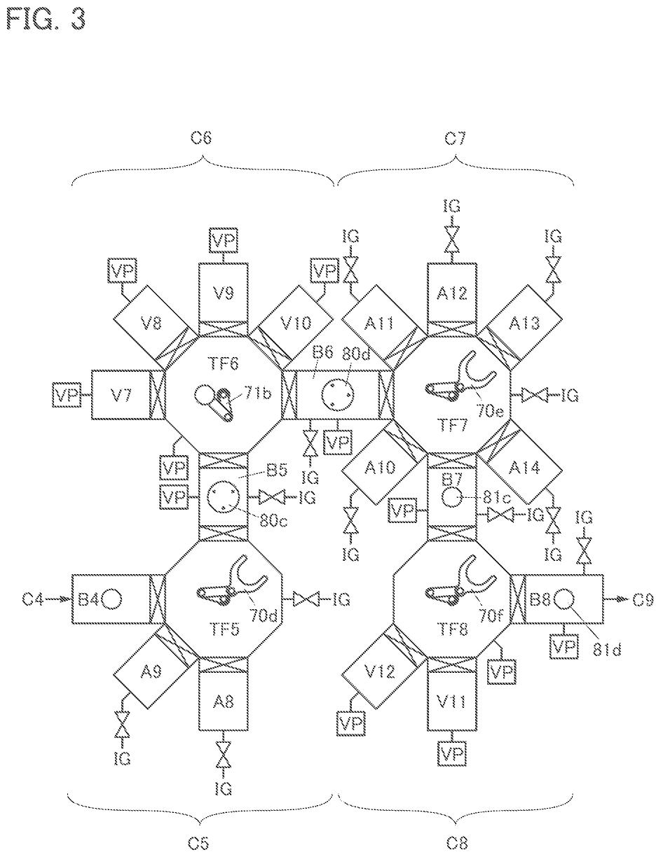

FIG. 2 is a top view illustrating the cluster C1 to the cluster C4. The cluster C1 is connected to the cluster C2 through a loadlock chamber B1. The cluster C2 is connected to the cluster C3 through a loadlock chamber B2. The cluster C3 is connected to the cluster C4 through a loadlock chamber B3. The cluster C4 is connected to the cluster C5 (see FIG. 3) through a loadlock chamber B4.

### <Normal-Pressure Process Apparatus A>

The cluster C1 and the cluster C3 each include normal-pressure process apparatuses A. The cluster C1 includes a transfer chamber TF1 and the normal-pressure process apparatuses A (normal-pressure process apparatuses A1 and A2) where processing is performed mainly under a normal pressure. The cluster C3 includes a transfer chamber TF3 and the normal-pressure process apparatuses A (normal-pressure process apparatuses A3 to A7). In the cluster C1, a load chamber LD is provided.

Note that the number of the normal-pressure process apparatuses A included in each of the clusters may be one or more depending on the purpose. Note that the normal-pressure process apparatus A is not limited to steps under a normal pressure, and the pressure of the normal-pressure process apparatus A may be controlled to a negative pressure or a positive pressure that shifts slightly from the normal pressure. In the case where a plurality of normal-pressure process apparatuses A are provided, the pressures therein may be different from each other.

Valves for introducing an inert gas (IG) are connected to the transfer chambers TF1 and TF3 and the normal-pressure process apparatuses A, whereby the atmosphere therein can be controlled to be an inert gas atmosphere. Examples of the inert gas that can be used include nitrogen and a noble gas such as argon or helium. In addition, the inert gas preferably has a low dew point (e.g., −50° C. or lower). When a step is performed under an atmosphere of an inert gas with a low dew point, entry of impurities can be prevented and a highly reliable organic EL element can be formed.

As the normal process apparatuses A included in the cluster C1, a cleaning apparatus, a baking apparatus, and the like can be employed. For example, a spin cleaning apparatus, a hot plate-type baking apparatus, and the like can be employed. The baking apparatus may be a vacuum baking apparatus.

As the normal-pressure process apparatuses A included in the cluster C3, apparatuses for performing a lithography step can be used. For example, in the case where a photolithography step is performed, a resin (photoresist) application apparatus, a light-exposure apparatus, a development apparatus, a baking apparatus, and the like can be employed. In the case where a nanoimprint lithography step is performed, a resin (e.g., a UV curable resin) application apparatus, a nanoimprint apparatus, and the like can be employed. In addition, depending on the usage, a cleaning apparatus, a wet etching apparatus, an application apparatus, a resist peeling apparatus, and the like may be employed as the normal-pressure process apparatuses A.

In the example of the cluster C1, the normal-pressure process apparatuses A1 and A2 are each connected to the transfer chamber TF1 through a gate valve. In the example of the cluster C3, the normal-pressure process apparatuses A3 to A7 are each connected to the transfer chamber TF3 through a gate valve. Providing the gate valve makes it possible to control atmospheric pressure, control the kind of an inert gas, and prevent cross contamination, for example.

The transfer chamber TF1 is connected to the load chamber through a gate valve. The transfer chamber TF1 is also connected to the loadlock chamber B1 through another gate valve. The transfer chamber TF1 is provided with a carrying device 70a. The carrying device 70a can carry the substrate into the normal-pressure process apparatus A from the load chamber LD. In addition, the carrying device 70a can take out the substrate from the normal-pressure process apparatus A and carry out the substrate to the loadlock chamber B1.

The transfer chamber TF3 is connected to the loadlock chamber B2 through a gate valve. The transfer chamber TF3 is also connected to the loadlock chamber B3 through another gate valve. The transfer chamber TF3 is provided with a carrying device 70b. The carrying device 70b can carry the substrate into the normal-pressure process apparatus A from the loadlock chamber B2. In addition, the carrying device 70b can take out the substrate from the normal-pressure process apparatus A and carry out the substrate to the loadlock chamber B3.

### <Vacuum Process Apparatus V>

The cluster C2 and the cluster C4 each include vacuum process apparatuses V. The cluster C2 includes a transfer chamber TF2 and the vacuum process apparatuses V (vacuum process apparatuses V1 to V4). The cluster C4 includes a transfer chamber TF4 and the vacuum process apparatuses V (vacuum process apparatuses V5 and V6).

Note that the number of the vacuum process apparatuses V included in each of the clusters may be one or more depending on the purpose. A vacuum pump VP is connected to each vacuum process apparatus V, and a gate valve is provided between each vacuum process apparatus V and the transfer chamber TF (transfer chambers TF2 and TF4). Thus, different processes can be performed in parallel in the vacuum process apparatuses V.

Note that the vacuum process means treatment in an environment where the pressure is controlled to be a reduced pressure. Thus, the vacuum process includes treatment for performing pressure control under a reduced pressure with introduction of a process gas, besides treatment under high vacuum.

The transfer chambers TF2 and TF4 are also provided with an independent vacuum pump VP, so that cross contamination during processes performed in the vacuum process apparatuses V can be prevented.

As the vacuum process apparatuses V included in the cluster C2, deposition apparatuses such as an evaporation apparatus, a sputtering apparatus, a CVD (Chemical Vapor Deposition) apparatus, and an ALD (Atomic Layer Deposition) apparatus can be employed, for example. As the CVD apparatus, a thermal CVD apparatus using heat, a PECVD apparatus (Plasma Enhanced CVD apparatus) using plasma, or the like can be used. As the ALD apparatus, a thermal ALD apparatus using heat, a PEALD apparatus (Plasma Enhanced ALD apparatus) using a plasma-excited reactant, or the like can be used.

As the vacuum process apparatuses V included in the cluster C4, a dry etching apparatus, an ashing apparatus, or the like can be employed, for example.

The transfer chamber TF2 is connected to the loadlock chamber B1 through a gate valve. The transfer chamber TF2 is also connected to the loadlock chamber B2 through another gate valve. The transfer chamber TF2 is provided with a carrying device 71a. The carrying device 71a can reverse the substrate placed in the loadlock chamber B1 and carry out the substrate to the vacuum process apparatus V. In addition, the carrying device 71a can take out the substrate from the vacuum process apparatus V, reverse the substrate, and carry out the substrate to the loadlock chamber B2.

The transfer chamber TF4 is connected to the loadlock chamber B3 through a gate valve. The transfer chamber TF4 is also connected to the loadlock chamber B4 through another gate valve. The transfer chamber TF4 is provided with a carrying device 70c. With the carrying device 70c, the substrate can be carried from the loadlock chamber B3 into the vacuum process apparatus V and carried out to the loadlock chamber B4.

The loadlock chambers B1, B2, B3, and B4 are each provided with a valve for introducing an inert gas and the vacuum pump VP. Thus, the loadlock chambers B1, B2, B3, and B4 can be controlled so as to be under a reduced pressure or an inert gas atmosphere. For example, in the case where the substrate is carried from the cluster C2 to the cluster C3, it is possible that the substrate is carried from the cluster C2 into the loadlock chamber B2 under a reduced pressure, and the substrate is carried out to the cluster C3 after the atmosphere in the loadlock chamber B2 is changed to an inert atmosphere.

Note that the carrying devices 70a, 70b, and 70c each have a mechanism for carrying the substrate placed on a hand portion. The hand portion may be provided with a vacuum adsorption mechanism or the like because the carrying devices 70b and 70c work under a normal pressure. The carrying device 71a has a mechanism for carrying the substrate fixed to the hand portion. For fixing the substrate, an electrostatic adsorption mechanism or the like can be employed, because the carrying device 71a works under a reduced pressure.

As described above, since the structures of the carrying devices 70a, 70b, and 70c are different from that of the carrying device 71a, stages 80a and 80b where the substrate can be placed on pins are provided in the loadlock chambers B1 are B2, respectively. In addition, stages 81a and 81b where the substrate can be placed on a plane are provided in the loadlock chambers B3 and B4, respectively. Note that these stages are just examples and a stage with another structure may be employed. Carrying in and out of the substrate in the loadlock chamber B1 will be described in detail later.

### <Cluster C5 to Cluster C8>

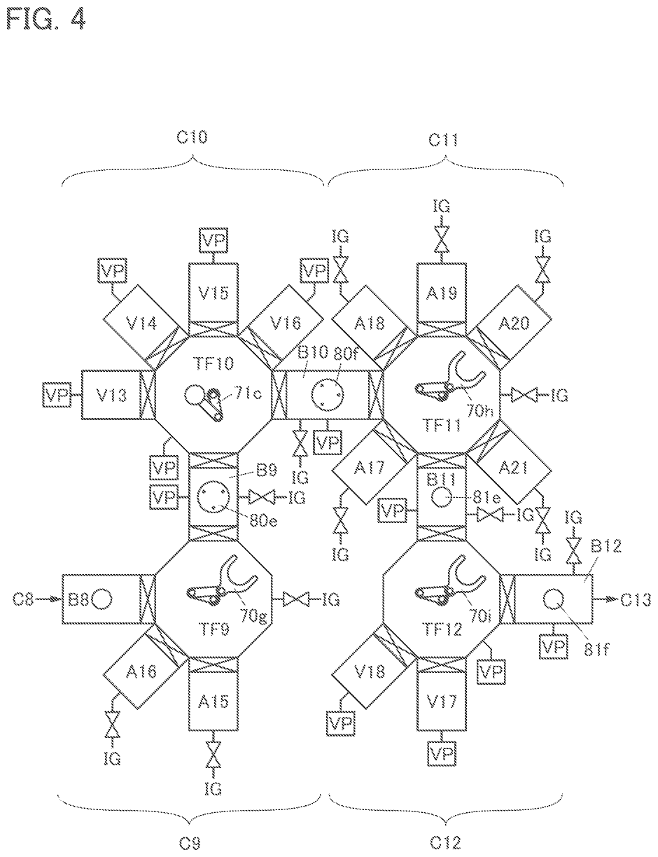

FIG. 3 is a top view illustrating the cluster C5 to the cluster C8. The cluster C5 is connected to the cluster C6 through a loadlock chamber B5. The cluster C6 is connected to the cluster C7 through a loadlock chamber B6. The cluster C7 is connected to the cluster C8 through a loadlock chamber B7. The cluster C8 is connected to the cluster C9 (see FIG. 4) through the loadlock chamber B8.

The basic structures of the cluster C5 to the cluster C8 are similar to those of the cluster C1 to the cluster C4. The cluster C5 corresponds to the cluster C1, the cluster C6 corresponds to the cluster C2, the cluster C7 corresponds to the cluster C3, and the cluster C8 corresponds to the cluster C4. Note that the load chamber LD in the cluster C1 is replaced with the loadlock chamber B4 in the cluster C5.

In addition, the loadlock chamber B5 corresponds to the loadlock chamber B1, the loadlock chamber B6 corresponds to the loadlock chamber B2, the loadlock chamber B7 corresponds to the loadlock chamber B3, and the loadlock chamber B8 corresponds to the loadlock chamber B4.

Structures only will be described below. For details of the clusters and the loadlock chambers, description of the cluster C1 to the cluster C4 and the loadlock chambers B1 to B4 can be referred to.

The cluster C5 and the cluster C7 each include normal-pressure process apparatuses A. The cluster C5 includes the transfer chamber TF5 and the normal-pressure process apparatuses A (normal-pressure process apparatuses A8 and A9) where processing is performed mainly under a normal pressure. The cluster C7 includes the transfer chamber TF7 and the normal-pressure process apparatuses A (normal-pressure process apparatuses A10 to A14).

The transfer chamber TF5 is connected to the loadlock chamber B4 through a gate valve. The transfer chamber TF5 is also connected to the loadlock chamber B5 through another gate valve. The transfer chamber TF5 is provided with a carrying device 70d. The carrying device 70d can carry the substrate into the normal-pressure process apparatus A from the loadlock chamber B4. In addition, the carrying device 70d can take out the substrate from the normal-pressure process apparatus A and carry out the substrate to the loadlock chamber B5.

The transfer chamber TF7 is connected to the loadlock chamber B6 through a gate valve. The transfer chamber TF7 is also connected to the loadlock chamber B7 through another gate valve. The transfer chamber TF7 is provided with the carrying device 70e. The carrying device 70d can carry the substrate into the normal-pressure process apparatus A from the loadlock chamber B6. In addition, the carrying device 70e can take out the substrate from the normal-pressure process apparatus A and carry out the substrate to the loadlock chamber B7.

The cluster C6 and the cluster C8 each include vacuum process apparatuses V. The cluster C6 includes a transfer chamber TF6 and the vacuum process apparatuses V (vacuum process apparatuses V7 to V10). The cluster C8 includes a transfer chamber TF8 and the vacuum process apparatuses V (vacuum process apparatuses V11 and V12).

The transfer chamber TF6 is connected to the loadlock chamber B5 through a gate valve. The transfer chamber TF6 is also connected to the loadlock chamber B6 through another gate valve. The transfer chamber TF6 is provided with a carrying device 71b. The carrying device 71b can reverse the substrate placed in the loadlock chamber B5 and carry out the substrate to the vacuum process apparatus V. The carrying device 71b can take out the substrate from the vacuum process apparatus V, reverse the substrate, and carry out the substrate to the loadlock chamber B6.

The transfer chamber TF8 is connected to the loadlock chamber B7 through a gate valve. The transfer chamber TF8 is also connected to the loadlock chamber B8 through another gate valve. The transfer chamber TF8 is provided with a carrying device 70f The carrying device 70f can carry the substrate from the loadlock chamber B7 into the vacuum process apparatus V. The carrying device 70f can take out the substrate from the vacuum process apparatus V can carry out the substrate to the loadlock chamber B8.

Stages 80c and 80d where a substrate can be placed on pins are provided in the loadlock chambers B5 and B6, respectively. Stages 81c and 81d where a substrate can be placed on a plane are provided in the loadlock chambers B7 and B8, respectively.

### <Cluster C9 to Cluster C12>

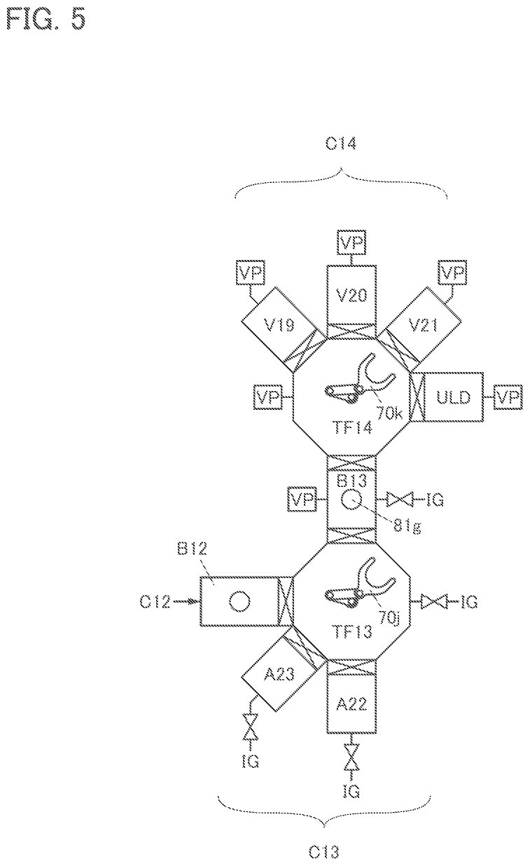

FIG. 4 is a top view illustrating the cluster C9 to a cluster C12. The cluster C9 is connected to a cluster C10 through a loadlock chamber B9. The cluster C10 is connected to the cluster C11 through a loadlock chamber B10. The cluster C11 is connected to the cluster C12 through a loadlock chamber B11. The cluster C12 is connected to the cluster C13 (see FIG. 5) through the loadlock chamber B12.

The basic structures of the cluster C9 to the cluster C12 are similar to those of the cluster C1 to the cluster C4. The cluster C9 corresponds to the cluster C1, the cluster C10 corresponds to the cluster C2, the cluster C11 corresponds to the cluster C3, and the cluster C12 corresponds to the cluster C4. Note that the load chamber LD in the cluster C1 is replaced with the loadlock chamber B8 in the cluster C9.

In addition, the loadlock chamber B9 corresponds to the loadlock chamber B1, the loadlock chamber B10 corresponds to the loadlock chamber B2, the loadlock chamber B11 corresponds to the loadlock chamber B3, and the loadlock chamber B12 corresponds to the loadlock chamber B4.

Structures only will be described below. For details of the clusters and the loadlock chambers, description of the cluster C1 to the cluster C4 and the loadlock chambers B1 to B4 can be referred to.

The cluster C9 and cluster C11 each include normal-pressure process apparatuses A. The cluster C9 includes a transfer chamber TF9 and the normal-pressure process apparatuses A (normal-pressure process apparatus A15 and A16) where processing is performed mainly under a normal pressure. The cluster C11 includes a transfer chamber TF11 and the normal-pressure process apparatuses A (normal-pressure process apparatus A17 to A21).

The transfer chamber TF9 is connected to the loadlock chamber B8 through a gate valve. The transfer chamber TF9 is also connected to the loadlock chamber B9 through another gate valve. The transfer chamber TF9 is provided with a carrying device 70g. The carrying device 70g can carry the substrate into the normal-pressure process apparatus A from the loadlock chamber B8. In addition, the carrying device 70g can take out the substrate from the normal-pressure process apparatus A and carry out the substrate to the loadlock chamber B9.

The transfer chamber TF11 is connected to the loadlock chamber B10 through a gate valve. The transfer chamber TF11 is also connected to the loadlock chamber B11 through another gate valve. The transfer chamber TF11 is provided with a carrying device 70h. The carrying device 70h can carry the substrate into the normal-pressure process apparatus A from the loadlock chamber B10. In addition, the carrying device 70h can take out the substrate from the normal-pressure process apparatus A and carry out the substrate to the loadlock chamber B11.

The cluster C10 and the cluster C12 each include vacuum process apparatuses V. The cluster C10 includes a transfer chamber TF10 and the vacuum process apparatuses V (vacuum process apparatuses V13 to V16). The cluster C12 includes a transfer chamber TF12 and the vacuum process apparatuses V (vacuum process apparatuses V17 and V18).

The transfer chamber TF10 is connected to the loadlock chamber B9 through a gate valve. The transfer chamber TF10 is also connected to the loadlock chamber B10 through another gate valve. The transfer chamber TF10 is provided with a carrying device 71c. The carrying device 71c can reverse the substrate placed in the loadlock chamber B9 and carry out the substrate to the vacuum process apparatus V. In addition, the carrying device 71c can take out the substrate from the vacuum process apparatus V, reverse the substrate, and carry out the substrate to the loadlock chamber B10.

The transfer chamber TF12 is connected to the loadlock chamber B11 through a gate valve. The transfer chamber TF12 is also connected to the loadlock chamber B12 through another gate valve. The transfer chamber TF12 is provided with a carrying device 70i. With the carrying device 70i, the substrate can be carried from the loadlock chamber B11 into the vacuum process apparatus V and carried out to the loadlock chamber B12.

Stages 80e and 80f where a substrate is placed on pins are provided in the loadlock chambers B9 and B10, respectively. Stages 81e and 81f where a substrate is placed on a plane are provided in the loadlock chambers B11 and B12, respectively.

### <Clusters C13 and C14>

FIG. 5 is a top view illustrating the clusters C13 and C14. The cluster C13 is connected to the cluster C14 through a loadlock chamber B13. Note that the description of portions that are in common with those in the clusters C1, C2, and the like is omitted.

The cluster C13 includes normal-pressure process apparatuses A. The cluster C13 includes a transfer chamber TF13 and the normal-pressure process apparatuses A (normal-pressure process apparatus A22 and A23) where processing is performed mainly under a normal pressure.

As the normal process apparatus A included in the cluster C13, an etching apparatus, a baking apparatus, and the like can be employed. For example, a wet etching apparatus, a hot plate-type baking apparatus, and the like can be employed. The baking apparatus may be a vacuum baking apparatus.

The transfer chamber TF13 is connected to the loadlock chamber B12 through a gate valve. The transfer chamber TF13 is also connected to the loadlock chamber B13 through another gate valve. The transfer chamber TF13 is provided with a carrying device 70j. The carrying device 70j can carry a substrate from the loadlock chamber B12 into the normal-pressure process apparatus A. In addition, the carrying device 70j can carry out the substrate taken from the normal-pressure process apparatus A into the loadlock chamber B13.

As the vacuum apparatuses V included in the cluster C14, for example, deposition apparatuses such as an evaporation apparatus, a sputtering apparatus, a CVD apparatus, and an ALD apparatus, an apparatus for attaching a counter substrate to a substrate, or the like can be employed.

The loadlock chamber B13 is provided with a valve for introducing an inert gas and the vacuum pump VP. Thus, the loadlock chamber B13 can be controlled so as to be under a reduced pressure or an inert gas atmosphere.

The transfer chamber TF14 is connected to the loadlock chamber B13 through a gate valve. The transfer chamber TF14 is also connected to an unload chamber ULD through another gate valve. The transfer chamber TF14 is provided with a carrying device 70k. The carrying device 70k can carry the substrate into the vacuum process apparatus V from the loadlock chamber B13. In addition, The carrying device 70k can take out the substrate from the vacuum process apparatus V and carry out the substrate to the unload chamber ULD.

With use of the manufacturing equipment having the above structure, highly reliable light-emitting device sealed with a protective film can be formed.

For example, the following steps can be performed successively in the equipment under a controlled atmosphere: a step of forming an organic EL element emitting light of a first color in the clusters C1 to C4; a step of forming an organic EL element emitting light of a second color in the clusters C5 to C8; a step of forming an organic EL element emitting light of a third color in the clusters C9 to C12; a step of removing an unnecessary element in the cluster C13, and a step of forming a protective film in the cluster C14. Details of these steps are described later.

### Structural Example 2

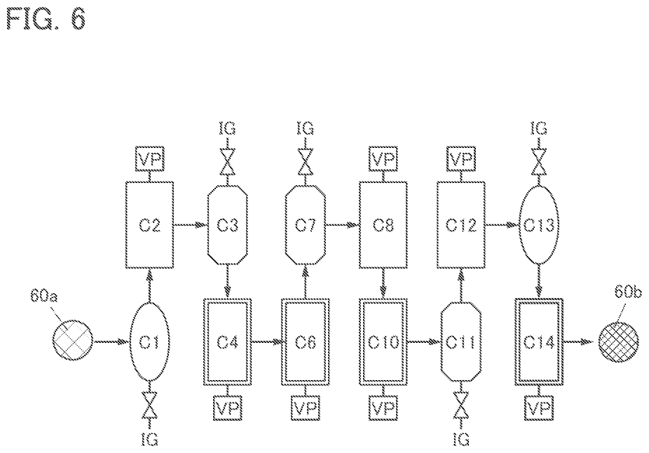

FIG. 6 is a block diagram illustrating manufacturing equipment of a light-emitting device different from that in FIG. 1. The manufacturing equipment in FIG. 6 is an example in which the clusters C1, C2, C3, C4, C6, C7, C8, C10, C11, C12, C13, and C14 are included, which is a structure excluding the clusters C5 and C9 from the manufacturing equipment illustrated in FIG. 1. The clusters C1, C2, C3, C4, C6, C7, C8, C10, C11, C12, C13, and C14 are connected in sequence and the substrate 60a brought into the cluster C1 can be taken out from the cluster C14 as the substrate 60b where light-emitting devices are formed.

In the manufacturing equipment illustrated in FIG. 1, the clusters C5 and C9 include a cleaning apparatus and a baking apparatus. The steps prior to the cleaning step are an etching (dry etching) and an ashing step. If residual gas components, residues, deposited matters, and the like in these steps do not affect adversely succeeding steps, the cleaning step can be omitted. In the case where the cleaning step is omitted, it is unnecessary to consider residual water in a substrate, and thus the baking step can also be unnecessary. Accordingly, the structure illustrated in FIG. 6 excluding the clusters C5 and C9 from the manufacturing equipment illustrated in FIG. 1 can be employed depending on cases. The total number of the clusters and the loadlock chambers can be reduced by excluding the clusters C5 and C9.

### <Cluster C1 to Cluster C4>

The structures of the cluster C1 to cluster C4 can be similar to those illustrated in FIG. 2. Note that the loadlock chamber B4 is connected to the cluster C6.

### <Clusters C6, C7, C8, and C10>

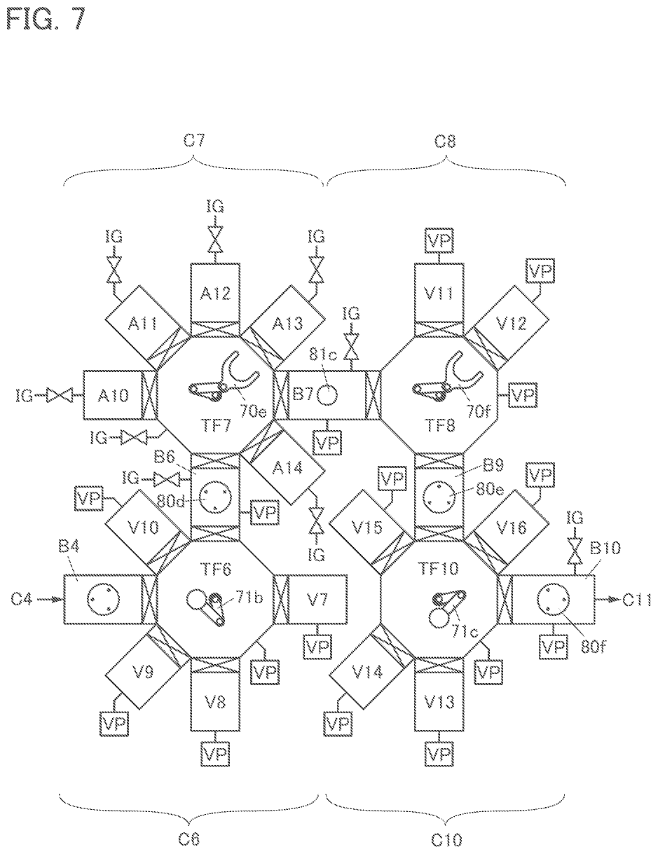

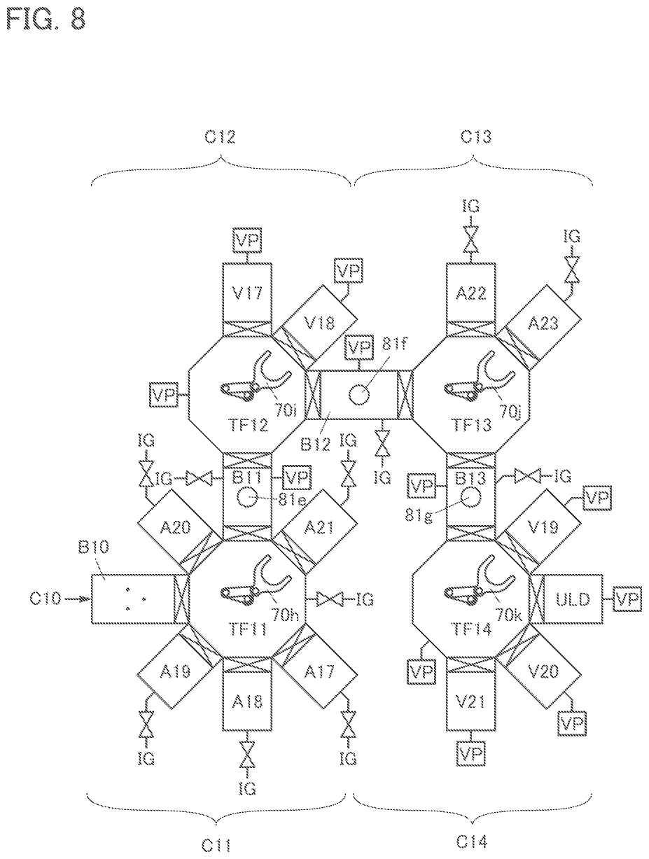

FIG. 7 is a top view illustrating the clusters C6, C7, C8, and C10. The cluster C6 is connected to the cluster C7 through the loadlock chamber B6. The cluster C7 is connected to the cluster C8 through the loadlock chamber B7. The cluster C8 is connected to the cluster C10 through the loadlock chamber B9. The cluster C10 is connected to the cluster C11 (see FIG. 8) through the loadlock chamber B10.

The connections between the clusters are described below. For the details of the clusters and the loadlock chambers, the description of the clusters C6, C7, C8, and C10 and the loadlock chambers B4, B7, B9, and B10 can be referred to.

The transfer chamber TF6 included in the cluster C6 is connected to the loadlock chamber B4 through a gate valve. The transfer chamber TF6 is also connected to the loadlock chamber B6 through another gate valve. The transfer chamber TF6 is provided with the carrying device 71b. The carrying device 71b can reverse the substrate placed in the loadlock chamber B4 and carry out the substrate to the vacuum process apparatus V. In addition, the carrying device 71b can take out the substrate from the vacuum process apparatus V, reverse the substrate, and carry out the substrate to the loadlock chamber B6.

The transfer chamber TF7 included in the cluster C7 is connected to the loadlock chamber B6 through a gate valve. The transfer chamber TF7 is also connected to the loadlock chamber B7 through another gate valve. The transfer chamber TF7 is provided with the carrying device 70e. The carrying device 70e can carry the substrate into the normal-pressure process apparatus A from the loadlock chamber B6. In addition, the carrying device 70e can take out the substrate from the normal-pressure process apparatus A and carry out the substrate to the loadlock chamber B7.

The transfer chamber TF8 included in the cluster C8 is connected to the loadlock chamber B7 through a gate valve. The transfer chamber TF8 is also connected to the loadlock chamber B9 through another gate valve. The transfer chamber TF8 is provided with the carrying device 70f The carrying device 70f can carry the substrate into the vacuum process apparatus V from the loadlock chamber B7. In addition, the carrying device 70f can take out the substrate from the vacuum process apparatus V and carry out the substrate to the loadlock chamber B9.

The transfer chamber TF10 included in the cluster C10 is connected to the loadlock chamber B9 through a gate valve. The transfer chamber TF10 is also connected to the loadlock chamber B10 through another gate valve. The transfer chamber TF10 is provided with the carrying device 71c. The carrying device 71c can reverse the substrate placed in the loadlock chamber B9 and carry out the substrate to the vacuum process apparatus V. In addition, the carrying device 71c can take out the substrate from the vacuum process apparatus V, reverse the substrate, and carry out the substrate to the loadlock chamber B10.

### <Clusters C11, C12, C13, and C14>

FIG. 8 is a top view illustrating the clusters C11, C12, C13, and C14. The cluster C11 is connected to the cluster C12 through the loadlock chamber B11. The cluster C12 is connected to the cluster C13 through the loadlock chamber B12. The cluster C13 is connected to the cluster C14 through the loadlock chamber B13.

The connections between the clusters are described below. For the details of the clusters and the loadlock chambers, the description of the clusters C11, C12, C13, and C14 and the loadlock chambers B11, B12, and B13 can be referred to.

The transfer chamber TF11 included in the cluster C11 is connected to the loadlock chamber B10 through a gate valve. The transfer chamber TF11 is also connected to the loadlock chamber B11 through another gate valve. The transfer chamber TF6 is provided with the carrying device 70h. The carrying device 70h can carry the substrate into the normal-pressure process apparatus A from the loadlock chamber B10. In addition, the carrying device 70h can take out the substrate from the normal-pressure process apparatus A and carry out the substrate to the loadlock chamber B11.

The transfer chamber TF12 included in the cluster C12 is connected to the loadlock chamber B11 through a gate valve. The transfer chamber TF12 is also connected to the loadlock chamber B12 through another gate valve. The transfer chamber TF12 is provided with the carrying device 70i. The carrying device 70i can carry the substrate into the vacuum process apparatus V from the loadlock chamber B11. In addition, the carrying device 70i can take out the substrate from the vacuum process apparatus V and carry out the substrate to the loadlock chamber B12.

The transfer chamber TF13 included in the cluster C13 is connected to the loadlock chamber B12 through a gate valve. The transfer chamber TF13 is also connected to the loadlock chamber B13 through another gate valve. The transfer chamber TF13 is provided with the carrying device 70j. The carrying device 70j can carry the substrate into the normal-pressure process apparatus A from the loadlock chamber B12. In addition, the carrying device 70j can take out the substrate from the normal-pressure process apparatus A and carry out the substrate to the loadlock chamber B13.

The transfer chamber TF14 included in the cluster C14 is connected to the loadlock chamber B13 through a gate valve. The transfer chamber TF14 is also connected to the unload chamber ULD through another gate valve. The transfer chamber TF13 is provided with the carrying device 70k. The carrying device 70k can carry the substrate into the vacuum process apparatus V from the loadlock chamber B13. In addition, the carrying device 70k can take out the substrate from the vacuum process apparatus V and carry out the substrate to the unload chamber ULD.

### Structure Example 3

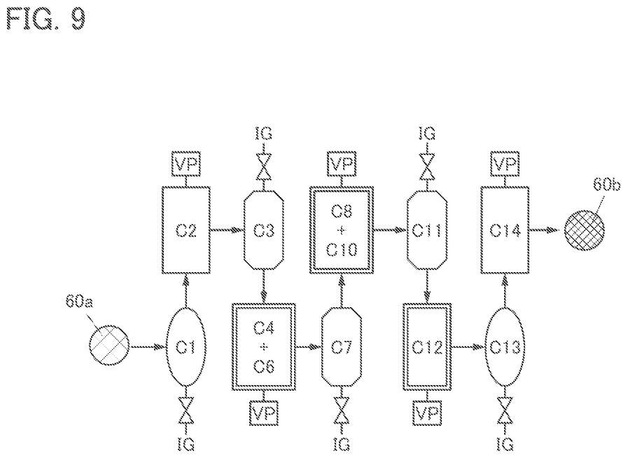

FIG. 9 is a block diagram illustrating a variation example of the manufacturing equipment of the light-emitting device illustrated in FIG. 6. In the manufacturing equipment illustrated in FIG. 9, the cluster C4 and cluster C6 are combined to one cluster and the cluster C8 and cluster C10 are combined to one cluster. Note that the combined clusters are referred to as a cluster C4+C6 and a cluster C8+C10.

In the manufacturing equipment illustrated in FIG. 6, the cluster C4 is connected to the cluster C6 through the loadlock chamber B4. That is, the substrate is carried into the cluster C6 from the cluster C4 and steps are performed.

Here, the cluster C4 and cluster C6 are each a cluster including the vacuum process apparatus V. There is an upper limit on the number of vacuum process apparatuses that can be connected to the transfer chamber; however, if the number of vacuum process apparatuses V included in each of the cluster C4 and the cluster C6 is below the upper limit, the both can be combined. The same applies to the cluster C8 and the cluster C10. By combining the cluster C4 and the cluster C6, the total number of clusters and loadlock chambers be reduced.

### <Clusters C1, C2, C3, and C4+C6>

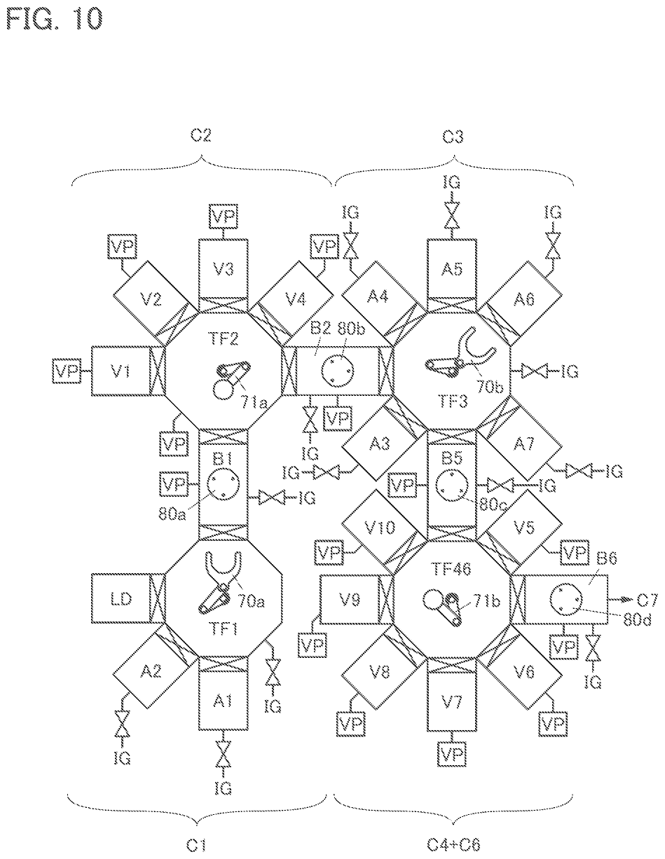

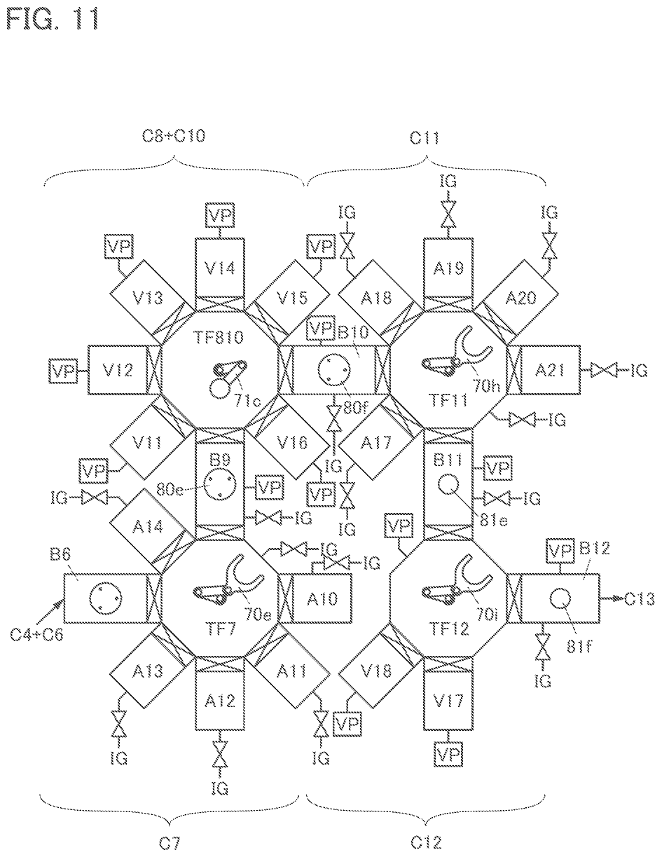

FIG. 10 is a top view illustrating the clusters C1, C2, C3, and C4+C6. The connections between the clusters C1 to C3 are similar to those illustrated in FIG. 2. The cluster C3 is connected to the cluster C4+C6 through the loadlock chamber B5. The cluster C4+C6 is connected to the cluster C7 (see FIG. 11) through the loadlock chamber B6.

The cluster C4+C6 includes a transfer chamber TF46 and the vacuum process apparatuses V. As the vacuum process apparatuses V (vacuum process apparatuses V5 to V10), an evaporation apparatus, a sputtering apparatus, a CVD apparatus, an ALD apparatus, an etching apparatus, an ashing apparatus, or the like can be used, for example.

The loadlock chambers B5 and B6 are each provided with a valve for introducing an inert gas and the vacuum pump VP. Thus, the loadlock chambers B5 and B6 can be controlled so as to be in a reduced pressure or an inert gas atmosphere.

The transfer chamber TF46 is connected to the loadlock chamber B5 through a gate valve. The transfer chamber TF46 is also connected to the loadlock chamber B6 through another gate valve. The transfer chamber TF46 is provided with the carrying device 71b. The carrying device 71b can carry the substrate from the loadlock chamber B5 to the vacuum process apparatus V. In addition, the carrying device 71b can take out the substrate from the vacuum process apparatus V and carry out the substrate to the loadlock chamber B6.

### <Clusters C7, C8+C10, C11, and C12>

FIG. 11 is a top view illustrating the clusters C7, C8+C10, C11, and C12. The connection between the clusters C11 and C12 is similar to that illustrated in FIG. 4. The cluster C7 is connected to the cluster C8+C10 through the loadlock chamber B9. The cluster C8+C10 is connected to the cluster C11 through the loadlock chamber B10.

The cluster C8+C10 includes a transfer chamber TF810 and the vacuum process apparatuses V. As the vacuum process apparatuses V (vacuum process apparatuses V11 to V16), an evaporation apparatus, a sputtering apparatus, a CVD apparatus, an ALD apparatus, an etching apparatus, an ashing apparatus, or the like can be used, for example.

The loadlock chambers B9 and B10 are each provided with a valve for introducing an inert gas and the vacuum pump VP. Thus, the loadlock chambers B9 and B10 can be controlled to have a reduced pressure atmosphere or an inert gas atmosphere therein.

The transfer chamber TF810 is connected to the loadlock chamber B9 through a gate valve. The transfer chamber TF810 is also connected to the loadlock chamber B10 through another gate valve. The transfer chamber TF810 is provided with the carrying device 71c. The carrying device 71c can carry the substrate from the loadlock chamber B9 to the vacuum process apparatus V. In addition, the carrying device 71c can take out the substrate from the vacuum process apparatus V and carry out the substrate to the loadlock chamber B10.

### <Clusters C13 and C14>

The structures of the clusters C13 and C14 can be similar to the structures illustrated in FIG. 5.

### <Substrate-Carrying Operation>

Next, an operation for carrying a substrate from the cluster C1 to the cluster C2 is described with reference to drawings. Note that description below can be applied to substrate-carrying operations between other clusters having a structure similar to that of the cluster C1 and other clusters having a structure similar to that of the cluster C2.

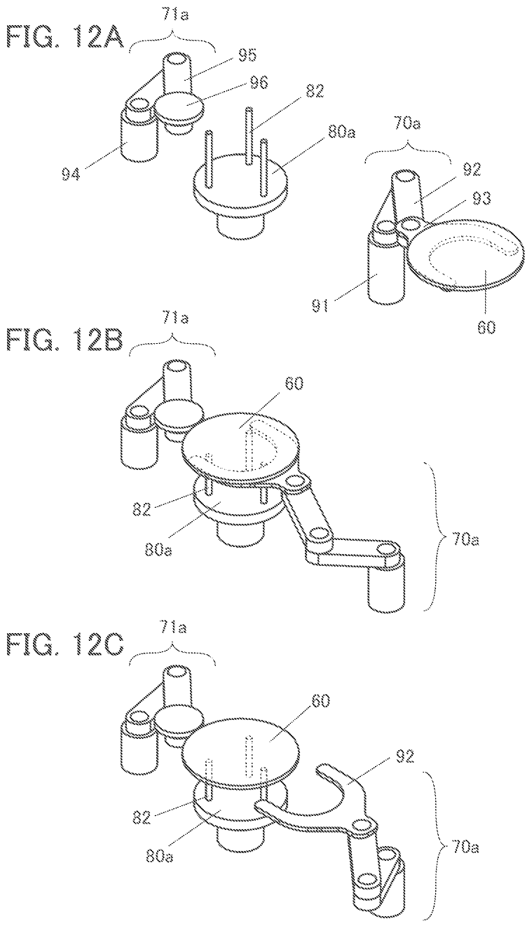

FIG. 12A illustrates the carrying device 70a included in the cluster C1, the stage 80a included in the loadlock chamber B1, and the carrying device 71a included in the cluster C2. In the illustration, chamber walls, gate valves, and the like are omitted for the sake of clarity.

The carrying device 70a includes a lifting mechanism 91, an arm 92, a hand portion 93. The hand portion 93 includes a plane with a cutout portion, and a substrate can be placed on the plane. The cluster C1 is a cluster including the normal-pressure process apparatuses A, and thus, a vacuum adsorption mechanism or the like may be provided in the hand portion 93. Alternatively, an electrostatic adsorption mechanism may be provided.

The carrying device 71a includes a lifting mechanism 94, an arm 95, a substrate fixing portion 96. The substrate fixing portion 96 includes a plane holding the substrate 60, and the size of the plane is smaller than the width of the cutout portion of the hand portion 93 of the carrying device 70a. The cluster C1 is a cluster including the vacuum process apparatuses V, and thus, the electrostatic adsorption mechanism is preferably provided in the substrate fixing portion 96. Furthermore, the carrying device 71a includes a substrate reversing mechanism described later.

The stage 80a includes pins 82 on which the substrate 60 is placed. A first length that connects the two pins 82 (excluding the diameters of the pins 82) is larger than the width of the substrate fixing portion 96. In addition, a second length that connects the two pins 82 (including the diameters of the pins 82) is smaller than the width of the cutout portion of the hand portion 93. As long as the substrate 60 can be fixed stably and the substrate fixing portion 96 is not interfered with the rear side of the substrate 60, a structure without pins may be employed. Note that the stage 80a may be provided with a lifting mechanism.

First, the substrate 60 held in the hand portion 93 of the carrying device 70a is carried to the stage 80a (see FIG. 12B), lifted down by the lifting mechanism 91, and placed on the pins 82 (see FIG. 12C).

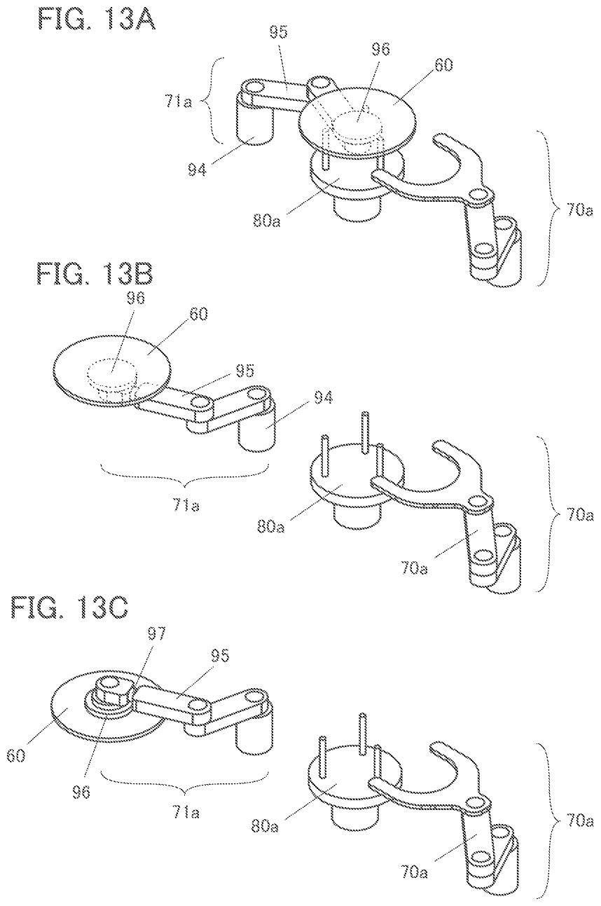

Next, the substrate fixing portion 96 facing upward of the carrying device 71a is inserted between the pins 82 of the stage 80a, and by raising the arm 95, the rear side of the substrate 60 is fixed on the substrate fixing portion 96 (see FIG. 13A).

Next, the substrate 60 is carried into the cluster C1 by further raising the arm 95 and through an expansion-contraction operation and a turning operation of the arm 95 (see FIG. 13B).

Then, the substrate 60 is reversed while being fixed on the substrate fixing portion 96, by a rotation mechanism 97 provided between the substrate fixing portion 96 and the arm 95 (see FIG. 13C). The reversed substrate 60 can be carried into a deposition apparatus or the like where the substrate is to be placed in a face-down mode.

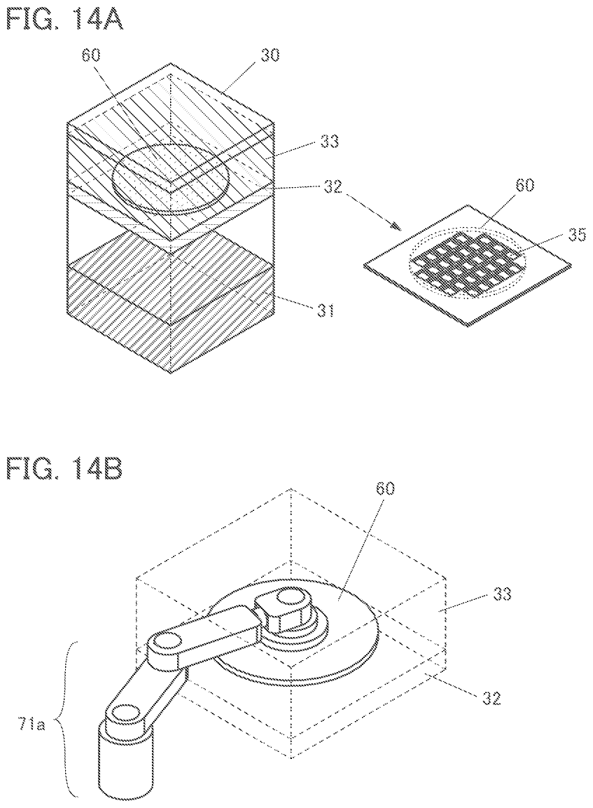

FIG. 14A is a diagram illustrating the vacuum process apparatus V in which a substrate is placed in a face-down mode; here, a deposition apparatus 30 is illustrated as an example. Note that for the sake of clarity, a chamber wall is illustrated as a transparent view and a gate valve is not illustrated in the diagram.

The deposition apparatus 30 includes a deposition material supply unit 31, a mask jig 32, and a substrate alignment unit 33. The deposition material supply unit 31 is provided with an evaporation source when the deposition apparatus 30 is an evaporation apparatus. Alternatively, the deposition material supply unit 31 is provided with a target (cathode) when the deposition apparatus 30 is a sputtering apparatus.

As illustrated in FIG. 14B, a substrate 60 in a reversed state can be carried in the substrate alignment unit 33. The mask jig 32 is located below the substrate alignment unit 33. A circuit and the like are provided on the surface of the substrate 60 in advance, and the substrate 60 is attached closely to the mask jig 32 so as to avoid deposition in an unnecessary area. At this time, the substrate alignment unit 33 performs the position alignment between a portion of the substrate 60 where deposited is needed and an opening portion 35 of the mask jig 32.

Structures such as light-emitting elements are formed in an opening portion 35; thus, the opening portion 35 may be adjusted depending on the purpose. For example, the size of the opening portion 35 can be determined depending on the size of an exposed region described below.

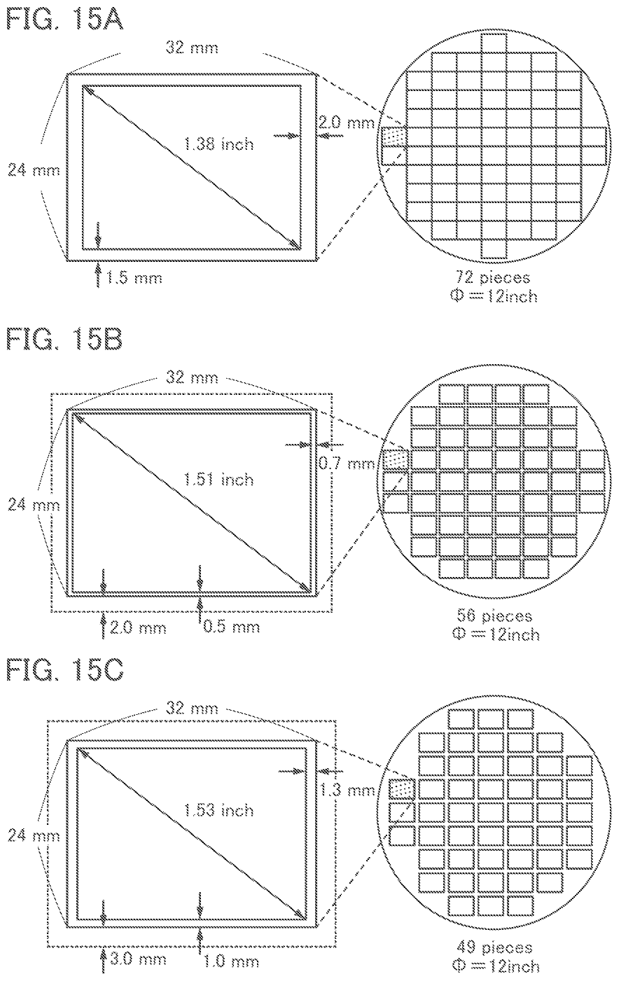

FIG. 15A to FIG. 15C illustrate examples of the number of display devices taken out from one substrate (e.g., silicon wafer) with a diameter ϕ=12 inches. Estimations illustrated in FIG. 15A to FIG. 15C are performed assuming that an external connection terminal is extracted from a rear surface with use of a through electrode. Thus, a display region can be set large. Note that a pad may be provided in the light-exposure region. In this case, the display region is reduced but has an effect of reducing the manufacturing cost for the structure of extracting the external connection terminal.

FIG. 15A to FIG. 15C illustrate examples of a case where the aspect ratio of each display region is 4:3.

FIG. 15A is an example where a sealing region is provided inside a light-exposure region (32 mm×24 mm) of a light-exposure apparatus. In the example of FIG. 15A, the width of the sealing region in the vertical direction is 1.5 mm and that in the horizontal direction is 2.0 mm. In this case, the display region has a size of 28 mm×21 mm (the aspect ratio is 4:3) and a diagonal size of approximately 1.38 inches. The number of display apparatuses taken from one substrate is 72. When the width of the sealing region in the vertical direction is 2.0 mm and that in the horizontal direction is 2.65 mm, the display region has a size of 26.7 mm×20 mm (the aspect ratio is 4:3) and a diagonal size of approximately 1.32 inches. Alternatively, when the width of the sealing region in the vertical direction is 3.0 mm and that in the horizontal direction is 4.0 mm, the display region has a size of 24 mm×18 mm (the aspect ratio is 4:3) and a diagonal size of approximately 1.18 inches. In each case, the number of display apparatuses taken from one substrate is 72.

FIG. 15B and FIG. 15C illustrate examples where a sealing region is provided outside a light-exposure region (32 mm×24 mm) of a light-exposure apparatus. In this case, the region except a space for the sealing region is exposed to light. A marker region is provided inside the light-exposure region. FIG. 15B illustrates an example of a case where the width of the marker region in the vertical direction is 0.5 mm and that in the horizontal direction is 0.7 mm, and the width of the sealing region is 2.0 mm. In this case, the display region of the display apparatus has a diagonal size of approximately 1.51 inches. The number of display apparatuses taken from one substrate is 56. Note that when the width of the marker region in the vertical direction is 1.0 mm and that in the horizontal direction is 1.3 mm, the display region has a diagonal size of approximately 1.45 inches. FIG. 15C illustrates an example of a case where the width of the marker region in the vertical direction is 0.5 mm and that in the horizontal direction is 0.7 mm, and the width of the sealing region is 3.0 mm. In this case, the display region of the display apparatus has a diagonal size of approximately 1.51 inches, and has the same structure as that in FIG. 15B. The number of display apparatuses taken from one substrate is 49, which is lower than that in the structure in FIG. 15B by approximately 13%.

This embodiment can be implemented in an appropriate combination with the structures described in the other embodiments.

### Embodiment 2

In this embodiment, manufacturing equipment different from that in Embodiment 1 will be described with reference to drawings. The manufacturing equipment in this embodiment is different from the manufacturing equipment in Embodiment 1 in that some of the deposition apparatuses are batch-type apparatuses. Parts in common with Embodiment 1 are described with common reference numerals.

### Structure Example 1

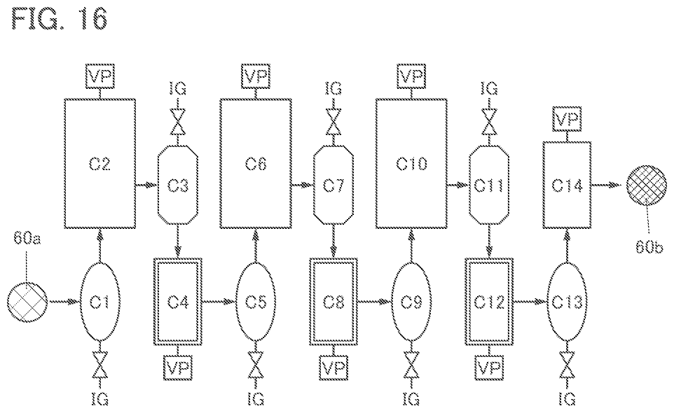

FIG. 16 is a block diagram illustrating the manufacturing equipment of a light-emitting device that is one embodiment of the present invention. The manufacturing equipment includes a plurality of clusters that are arranged in the order of process steps. Note that in this specification, a group of apparatuses which shares a carrying device or the like is called a cluster. A substrate where a light-emitting device is formed is moved between the clusters in sequence, so that the steps are conducted.

The manufacturing equipment illustrated in FIG. 16 is an example including the cluster C1 to the cluster C14. The cluster C1 to the cluster C14 are sequentially connected and the substrate 60a taken into the cluster C1 can be taken out, from the cluster C14, as the substrate 60b where the light-emitting device is formed.

The clusters C1, C3, C5, C7, C9, C11, and C13 each include a group of apparatuses for performing a process under atmosphere control. The clusters C2, C4, C6, C10, C12, and C14 each include a group of apparatuses for performing vacuum processing (processing under reduced pressure).

The clusters C1, C5, and C9 each include apparatuses mainly for cleaning and baking the substrate, and the like. The clusters C2, C6, and C10 each include apparatuses mainly for forming an organic compound included in the light-emitting device, and the like. The clusters C3, C7, and C11 each include apparatuses mainly for performing a lithography step, and the like. The clusters C4, C8, and C12 each include apparatuses mainly for performing an etching step and an ashing step, and the like. The cluster C13 includes apparatuses for performing an etching step and cleaning the substrate, and the like. The cluster C14 includes apparatuses mainly for forming an organic compound included in the light-emitting device and forming a protective film to seal the light-emitting device, and the like.

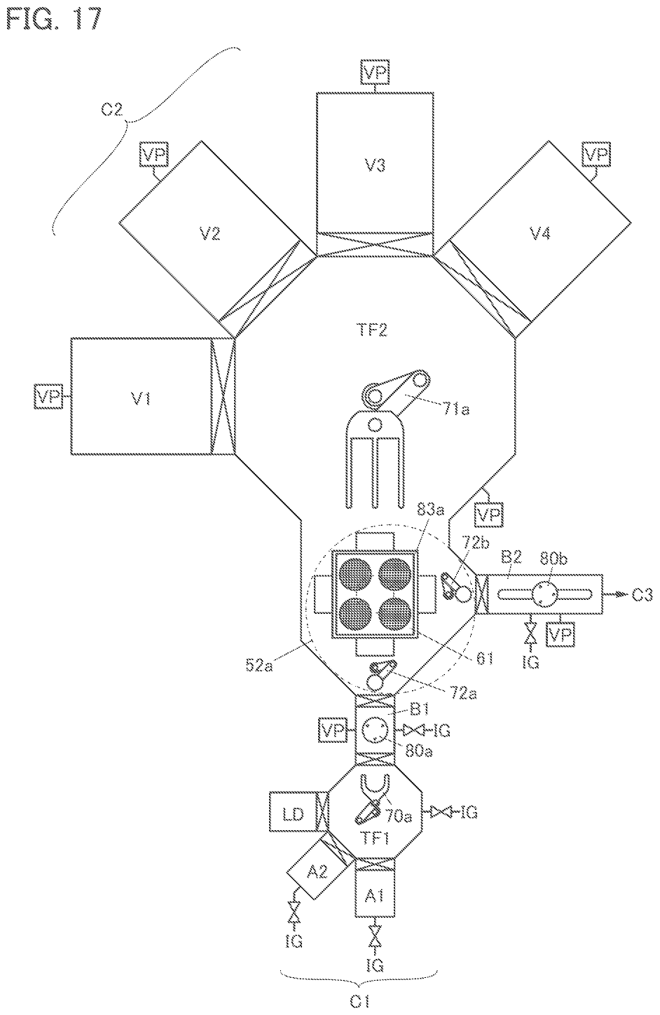

Next, the cluster C1 to the cluster C14 are described in detail with reference to the top views in FIG. 17 to FIG. 20.

### <Cluster C1 to Cluster C4>

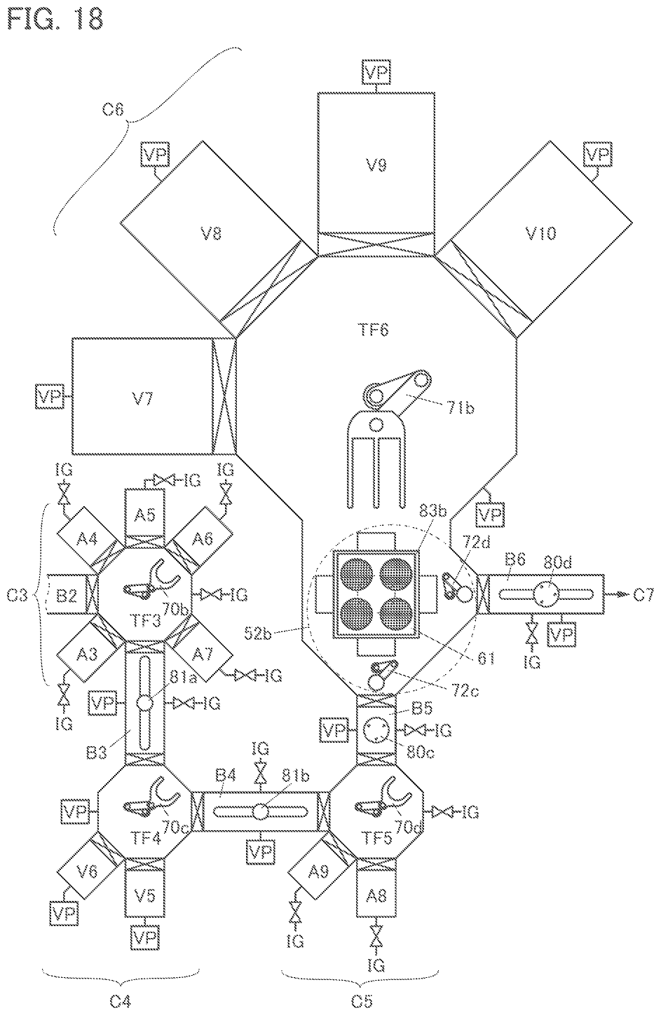

The cluster C1 to cluster C4 are described with reference to FIG. 17 and FIG. 18. The cluster C1 is connected to the cluster C2 through the loadlock chamber B1. The cluster C2 is connected to the cluster C3 through the loadlock chamber B2. The cluster C3 is connected to the cluster C4 through the loadlock chamber B3. The cluster C4 is connected to the cluster C5 through the loadlock chamber B4.

### <Normal-Pressure Process Apparatus A>

The cluster C1 and the cluster C3 each include the normal-pressure process apparatus A. The cluster C1 includes the transfer chamber TF1 and the normal-pressure process apparatuses A (normal-pressure process apparatuses A1 and A2) where a process is performed mainly under a normal pressure. The cluster C3 includes the transfer chamber TF3 and the normal-pressure process apparatuses A (normal-pressure process apparatuses A3 to A7). In the cluster C1, the load chamber LD is provided.

Note that the number of the normal-pressure process apparatuses A included in the cluster C1 and the cluster C3 may be one or more depending on the purpose. Note that the normal-pressure process apparatus A is not limited to steps under a normal pressure, and the pressure of the normal-pressure process apparatus A may be controlled to a negative pressure or a positive pressure that shifts slightly from the normal pressure. In the case where a plurality of the normal-pressure process apparatuses A are provided, the atmospheric pressures therein may be different from each other.

Valves for introducing an inert gas (IG) are connected to the transfer chambers TF1 and TF3 and the normal-pressure process apparatuses A, whereby the atmosphere therein can be controlled to be an inert gas atmosphere. Examples of the inert gas that can be used include nitrogen and a noble gas such as argon or helium. In addition, the inert gas preferably has a low dew point (e.g., −50° C. or lower). When a step is performed under an atmosphere of an inert gas with a low dew point, entry of impurities can be prevented and a highly reliable organic EL element can be formed.

As the normal process apparatuses A included in the cluster C1, a cleaning apparatus, a baking apparatus, and the like can be employed. For example, a spin cleaning apparatus, a hot plate-type baking apparatus, and the like can be employed. The baking apparatus may be a vacuum baking apparatus.

As the normal-pressure process apparatuses A included in the cluster C3, apparatuses for performing a lithography step can be used. For example, in the case where a photolithography step is performed, a resin (photoresist) application apparatus, a light-exposure apparatus, a development apparatus, a baking apparatus, and the like can be employed. In the case where a nanoimprint lithography step is performed, a resin (e.g., a UV curable resin) application apparatus, a nanoimprint apparatus, and the like can be employed. In addition, depending on the usage, a cleaning apparatus, a wet etching apparatus, an application apparatus, a resist peeling apparatus, and the like may be employed as the normal-pressure process apparatuses A.

In the example of the cluster C1, the normal-pressure process apparatuses A1 and A2 are each connected to the transfer chamber TF1 through a gate valve. In the example of the cluster C3, the normal-pressure process apparatuses A3 to A7 are each connected to the transfer chamber TF3 through a gate valve. Providing the gate valve makes it possible to control atmospheric pressure, control the kind of an inert gas, and prevent cross contamination, for example.

The transfer chamber TF1 is connected to the load chamber through a gate valve. The transfer chamber TF1 is also connected to the loadlock chamber B1 through another gate valve. The transfer chamber TF1 is provided with the carrying device 70a. The carrying device 70a can carry the substrate into the normal-pressure process apparatus A from the load chamber LD. In addition, the carrying device 70a can take out the substrate from the normal-pressure process apparatus A and carry out the substrate to the loadlock chamber B1.

The transfer chamber TF3 is connected to the loadlock chamber B2 through a gate valve. The transfer chamber TF3 is also connected to the loadlock chamber B3 through another gate valve. The transfer chamber TF3 is provided with the carrying device 70b. The carrying device 70b can carry the substrate into the normal-pressure process apparatus A from the loadlock chamber B2. In addition, the carrying device 70b can take out the substrate from the normal-pressure process apparatus A and carry out the substrate to the loadlock chamber B3.

### <Vacuum Process Apparatus V>

The cluster C2 and the cluster C4 each include vacuum process apparatuses V. The cluster C2 includes the transfer chamber TF2 and the vacuum process apparatuses V (vacuum process apparatuses V1 to V4). The cluster C4 includes the transfer chamber TF4 and the vacuum process apparatuses V (vacuum process apparatuses V5 and V6).

Note that the number of the vacuum process apparatuses V included in the cluster C2 and the cluster C4 may be one or more depending on the purpose. A vacuum pump VP is connected to each vacuum process apparatus V, and a gate valve is provided between each vacuum process apparatus V and the transfer chamber TF (transfer chambers TF2 and TF4). Thus, different processes can be performed in parallel in the vacuum process apparatuses V.

Note that the vacuum process means treatment in an environment where the pressure is controlled to be a reduced pressure. Thus, the vacuum process includes treatment for performing pressure control under a reduced pressure with introduction of a process gas, besides treatment under high vacuum.

The transfer chambers TF2 and TF4 are also provided with an independent vacuum pump VP, so that cross contamination during processes performed in the vacuum process apparatuses V can be prevented.

As the vacuum process apparatuses V included in the cluster C2, deposition apparatuses such as an evaporation apparatus, a sputtering apparatus, a CVD (Chemical Vapor Deposition) apparatus, and an ALD (Atomic Layer Deposition) apparatus can be employed, for example. As the CVD apparatus, a thermal CVD apparatus using heat, a PECVD apparatus (Plasma Enhanced CVD apparatus) using plasma, or the like can be used. As the ALD apparatus, a thermal ALD apparatus using heat, a PEALD apparatus (Plasma Enhanced ALD apparatus) using a plasma-excited reactant, or the like can be used.

As the vacuum process apparatuses V included in the cluster C4, a dry etching apparatus, an ashing apparatus, or the like can be employed, for example.

The transfer chamber TF2 is connected to the loadlock chamber B1 through a gate valve. The transfer chamber TF2 is also connected to the loadlock chamber B2 through another gate valve. The transfer chamber TF2 is provided with the carrying device 71a and a substrate transfer device 52a.

The substrate transfer device 52a includes a stage 83a and carrying devices 72a and 72b. A mask jig 61 can be placed on the stage 83a. A plurality of substrates can be mounted on the mask jig 61, and the carrying device 71a can carry the substrates mounted on the mask jig 61 into the vacuum process apparatuses V. Furthermore, the stage 83a can be moved in the X direction, the Y direction, and the θ direction.

The carrying device 72a can reverse the substrate placed in the loadlock chamber B1 and mount the substrate on the mask jig 61. The carrying device 72b can take out the substrate from the mask jig 61, reverse the substrate, and carry out the substrate to the loadlock chamber B2. Details of these operations are described later.

Note that as the mask jig 61, a plurality of kinds of mask jigs can be used. The mask jig can be stored in each vacuum process apparatus V and can be carried in and out with the carrying device 71a. Alternatively, the storage chamber for the mask jig 61 may be provided at the position where the vacuum process apparatus V is provided.

Note that as described above, since the vacuum process apparatus V included in the cluster C2 is a batch-type apparatus in which substrates mounted on the mask jig 61 are carried and processed, the cluster C2 becomes large. On the other hand, the clusters C1, C3, and C4 are of single-wafer types, and thus become small.

The transfer chamber TF4 is connected to the loadlock chamber B3 through a gate valve. The transfer chamber TF4 is also connected to the loadlock chamber B4 through another gate valve. The transfer chamber TF4 is provided with the carrying device 70c. With the carrying device 70c, the substrate can be carried from the loadlock chamber B3 into the vacuum process apparatus V and then carried out to the loadlock chamber B4.

The loadlock chambers B1, B2, B3, and B4 are each provided with a valve for introducing an inert gas and the vacuum pump VP. Thus, the loadlock chambers B1, B2, B3, and B4 can be controlled so as to be under a reduced pressure or an inert gas atmosphere. For example, in the case where the substrate is carried from the cluster C2 to the cluster C3, it is possible that the substrate is carried from the cluster C2 into the loadlock chamber B2 under a reduced pressure, and the substrate is carried out to the cluster C3 after the atmosphere in the loadlock chamber B2 is changed to an inert atmosphere.

Note that the carrying device 70a, 70b, and 70c and the carrying device 71a each have a mechanism for carrying the substrate placed on a hand portion. The hand portion may be provided with a vacuum adsorption mechanism because the carrying devices 70b and 70c work under a normal pressure. The carrying devices 72a and 72b each include a mechanism for carrying the substrate fixed to the hand portion. For fixing the substrate, an electrostatic adsorption mechanism or the like may be employed, because the carrying devices 72a and 72b work under a reduced pressure.

As described above, since the structures of the carrying devices 70a, 70b, and 70c are different from those of the carrying devices 72a and 72b, the stages 80a and 80b where the substrate can be placed on pins are provided in the loadlock chambers B1 are B2, respectively. In addition, the stages 81a and 81b where the substrate can be placed on a plane are provided in the loadlock chambers B3 and B4, respectively. Note that these stages are just examples and a stage with another structure may be employed. Carrying in and out of the substrate in the loadlock chamber B1 will be described in detail later.

### <Cluster C5 to Cluster C8>

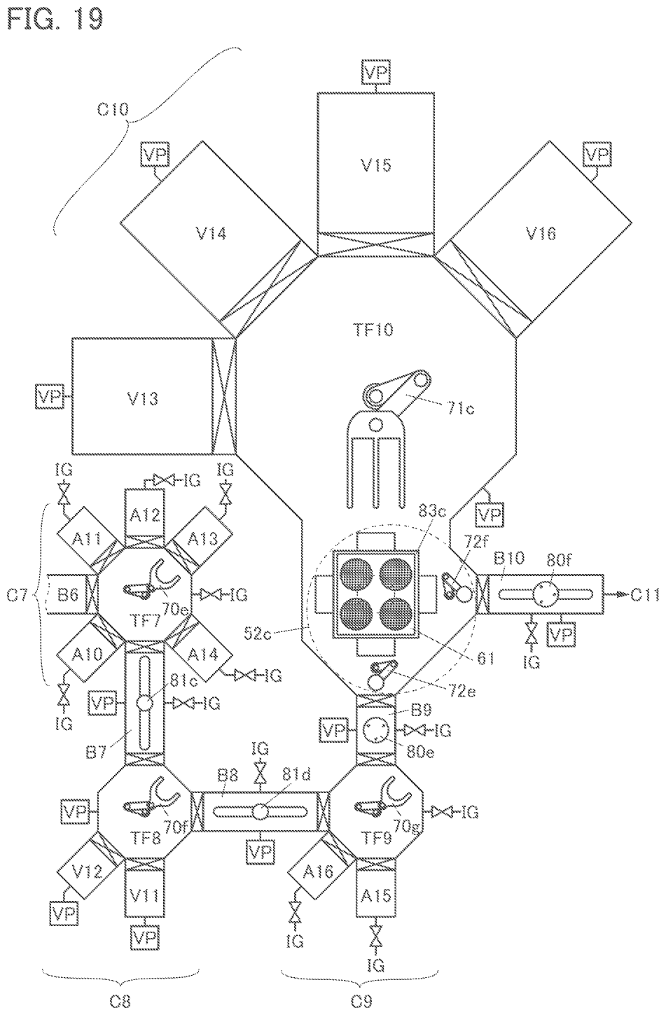

The cluster C5 to the cluster C8 are described with reference to FIG. 18 and FIG. 19. The cluster C5 is connected to the cluster C6 through the loadlock chamber B5. The cluster C6 is connected to the cluster C7 through the loadlock chamber B6. The cluster C7 is connected to the cluster C8 through the loadlock chamber B7. The cluster C8 is connected to the cluster C9 (see FIG. 19) through the loadlock chamber B8.

The basic structures of the cluster C5 to the cluster C8 are similar to those of the cluster C1 to the cluster C4. The cluster C5 corresponds to the cluster C1, the cluster C6 corresponds to the cluster C2, the cluster C7 corresponds to the cluster C3, and the cluster C8 corresponds to the cluster C4. Note that the load chamber LD in the cluster C1 is replaced with the loadlock chamber B4 in the cluster C5.

In addition, the loadlock chamber B5 corresponds to the loadlock chamber B1, the loadlock chamber B6 corresponds to the loadlock chamber B2, the loadlock chamber B7 corresponds to the loadlock chamber B3, and the loadlock chamber B8 corresponds to the loadlock chamber B4.

Structures only will be described below. For details of the clusters and the loadlock chambers, description of the cluster C1 to the cluster C4 and the loadlock chambers B1 to B4 can be referred to.

The cluster C5 and the cluster C7 each include normal-pressure process apparatuses A. The cluster C5 includes the transfer chamber TF5 and the normal-pressure process apparatuses A (normal-pressure process apparatuses A8 and A9) where processing is performed mainly under a normal pressure. The cluster C7 includes the transfer chamber TF7 and the normal-pressure process apparatuses A (normal-pressure process apparatuses A10 to A14).

The transfer chamber TF5 is connected to the loadlock chamber B4 through a gate valve. The transfer chamber TF5 is also connected to the loadlock chamber B5 through another gate valve. The transfer chamber TF5 is provided with the carrying device 70d. The carrying device 70d can carry the substrate into the normal-pressure process apparatus A from the loadlock chamber B4. In addition, the carrying device 70d can take out the substrate from the normal-pressure process apparatus A and carry out the substrate to the loadlock chamber B5.

The C6 and the clusters C8 each include vacuum process apparatuses V. The cluster C6 includes the transfer chamber TF6 and the vacuum process apparatuses V (vacuum process apparatuses V7 to V10). The cluster C8 includes the transfer chamber TF8 and the vacuum process apparatuses V (vacuum process apparatuses V11 and V12).

The transfer chamber TF6 is connected to the loadlock chamber B5 through a gate valve. The transfer chamber TF6 is also connected to the loadlock chamber B6 through another gate valve. The transfer chamber TF6 is provided with the carrying device 71b and a substrate transfer device 52b.

The substrate transfer device 52b includes a stage 83b and carrying devices 72c and 72d. The mask jig 61 can be placed on the stage 83b. The carrying device 71b can carry substrates mounted on the mask jig 61 into the vacuum process apparatuses V. Furthermore, the stage 83b can be moved in the X direction, the Y direction, and the θ direction.

The transfer chamber TF7 is connected to the loadlock chamber B6 through a gate valve. The transfer chamber TF7 is also connected to the loadlock chamber B7 through another gate valve. The transfer chamber TF7 is provided with the carrying device 70e. The carrying device 70d can carry the substrate into the normal-pressure process apparatus A from the loadlock chamber B6. In addition, the carrying device 70e can take out the substrate from the normal-pressure process apparatus A and carry out the substrate to the loadlock chamber B7.

The carrying device 72c can reverse the substrate placed in the loadlock chamber B5 and mount the substrate on the mask jig 61. The carrying device 72d can take out the substrate from the mask jig 61, reverse the substrate, and carry out the substrate to the loadlock chamber B6.

The transfer chamber TF8 is connected to the loadlock chamber B7 through a gate valve. The transfer chamber TF8 is also connected to the loadlock chamber B8 through another gate valve. The transfer chamber TF8 is provided with the carrying device 70f The carrying device 70f can carry the substrate from the loadlock chamber B7 into the vacuum process apparatus V. In addition, the carrying device 70f can take out the substrate from the vacuum process apparatus V and carry out the substrate to the loadlock chamber B8.

The stages 80c and 80d where a substrate can be placed on pins are provided in the loadlock chambers B5 and B6, respectively. In addition, the stages 81c and 81d where a substrate can be placed on a plane are provided in the loadlock chambers B7 and B8, respectively.

### <Cluster C9 to Cluster C12>

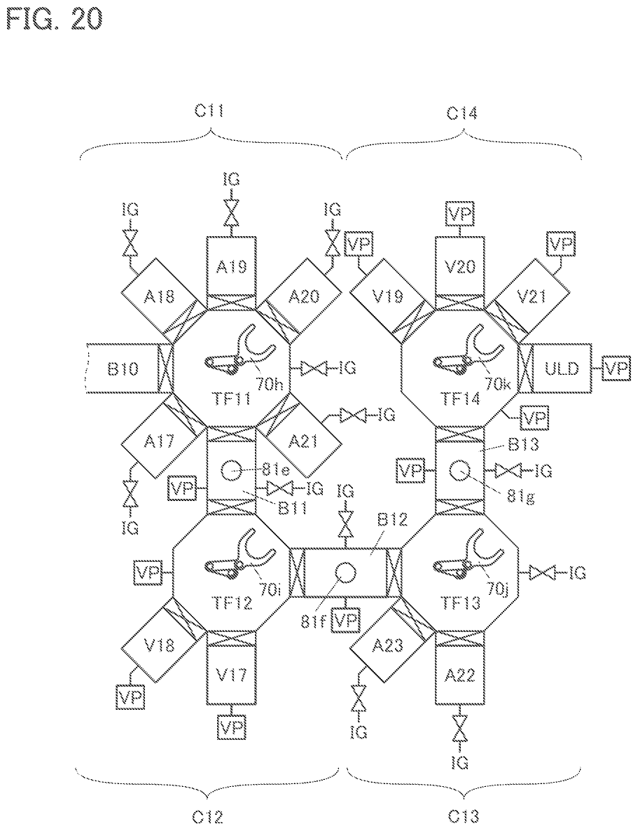

The cluster C9 to the cluster C12 are described with reference to FIG. 19 and FIG. 20. The cluster C9 is connected to a cluster C10 through the loadlock chamber B9. The cluster C10 is connected to the cluster C11 through the loadlock chamber B10. The cluster C11 is connected to the cluster C12 through the loadlock chamber B11. The cluster C12 is connected to the cluster C13 (see FIG. 20) through the loadlock chamber B12.

The basic structures of the cluster C9 to the cluster C12 are similar to those of the cluster C1 to the cluster C4. The cluster C9 corresponds to the cluster C1, the cluster C10 corresponds to the cluster C2, the cluster C11 corresponds to the cluster C3, and the cluster C12 corresponds to the cluster C4. Note that the load chamber LD in the cluster C1 is replaced with the loadlock chamber B8 in the cluster C9.

In addition, the loadlock chamber B9 corresponds to the loadlock chamber B1, the loadlock chamber B10 corresponds to the loadlock chamber B2, the loadlock chamber B11 corresponds to the loadlock chamber B3, and the loadlock chamber B12 corresponds to the loadlock chamber B4.

Structures only will be described below. For details of the clusters and the loadlock chambers, description of the cluster C1 to the cluster C4 and the loadlock chambers B1 to B4 can be referred to.

The cluster C9 and cluster C11 each include the normal-pressure process apparatuses A. The cluster C9 includes the transfer chamber TF9 and the normal-pressure process apparatuses A (normal-pressure process apparatus A15 and A16) where processing is performed under a normal pressure. The cluster C11 includes the transfer chamber TF11 and the normal-pressure process apparatuses A (normal-pressure process apparatus A17 to A21).

The transfer chamber TF9 is connected to the loadlock chamber B8 through a gate valve. The transfer chamber TF9 is also connected to the loadlock chamber B9 through another gate valve. The transfer chamber TF9 is provided with the carrying device 70g. The carrying device 70g can carry the substrate into the normal-pressure process apparatus A from the loadlock chamber B8. In addition, the carrying device 70g can take out the substrate from the normal-pressure process apparatus A and carry out the substrate to the loadlock chamber B9.

The transfer chamber TF11 is connected to the loadlock chamber B10 through a gate valve. The transfer chamber TF11 is also connected to the loadlock chamber B11 through another gate valve. The transfer chamber TF11 is provided with the carrying device 70h. The carrying device 70h can carry the substrate into the normal-pressure process apparatus A from the loadlock chamber B10. In addition, the carrying device 70h can take out the substrate from the normal-pressure process apparatus A and carry out the substrate to the loadlock chamber B11.

The cluster C10 and the cluster C12 each include vacuum process apparatuses V. The cluster C10 includes the transfer chamber TF10 and the vacuum process apparatuses V (vacuum process apparatuses V13 to V16). The cluster C12 includes the transfer chamber TF12 and the vacuum process apparatuses V (vacuum process apparatuses V17 and V18).

The transfer chamber TF10 is connected to the loadlock chamber B9 through a gate valve. The transfer chamber TF10 is also connected to the loadlock chamber B10 through another gate valve. The transfer chamber TF10 is provided with the carrying device 71c and a substrate transfer device 52c.

The substrate transfer device 52c includes a stage 83c and carrying devices 72e and 72f The mask jig 61 can be placed on the stage 83c. The carrying device 71c can carry substrates mounted on the mask jig 61 into the vacuum process apparatuses V. Furthermore, the stage 83c can be moved in the X direction, the Y direction, and the θ direction.

The carrying device 72e can reverse the substrate placed in the loadlock chamber B9 and mount the substrate on the mask jig 61. In addition, the carrying device 72f can take out the substrate from the mask jig 61, reverse the substrate, and carry out the substrate to the loadlock chamber B10.

The transfer chamber TF12 is connected to the loadlock chamber B11 through a gate valve. The transfer chamber TF12 is also connected to the loadlock chamber B12 through another gate valve. The transfer chamber TF12 is provided with the carrying device 70i. With the carrying device 70i, the substrate can be carried into the vacuum process apparatus V from the loadlock chamber B11 and then carried out to the loadlock chamber B12.

The stages 80e and 80f where a substrate can be placed on pins are provided in the loadlock chambers B9 and B10, respectively. The stages 81e and 81f where a substrate can be placed on a plane are provided in the loadlock chambers B11 and B12, respectively.

### <Clusters C13 and C14>

The clusters C13 and C14 are described with reference to FIG. 20. The cluster C13 is connected to the cluster C14 through the loadlock chamber B13. Note that the description of portions that are in common with the clusters C1, C2, and the like is omitted.

The cluster C13 includes normal-pressure process apparatuses A. The cluster C13 includes the transfer chamber TF13 and the normal-pressure process apparatuses A (normal-pressure process apparatus A22 and A23) where processing is performed mainly under a normal pressure.

As the normal process apparatus A included in the cluster C13, an etching apparatus, a baking apparatus, and the like can be employed. For example, a wet etching apparatus, a hot plate-type baking apparatus, and the like can be employed. The baking apparatus may be a vacuum baking apparatus.

The transfer chamber TF13 is connected to the loadlock chamber B12 through a gate valve The transfer chamber TF13 is also connected to the loadlock chamber B13 through another gate valve. The transfer chamber TF13 is provided with the carrying device 70j. The carrying device 70j can carry the substrate from the loadlock chamber B12 into the normal-pressure process apparatus A. In addition, the carrying device 70j can take out the substrate from the normal-pressure process apparatus A and carry out the substrate to the loadlock chamber B13.

As the vacuum apparatuses V included in the cluster C14, for example, deposition apparatuses such as an evaporation apparatus, a sputtering apparatus, a CVD apparatus, and an ALD apparatus, and an apparatus for attaching a counter substrate to a substrate can be employed.

The loadlock chamber B13 is provided with a valve for introducing an inert gas and the vacuum pump VP. Thus, the loadlock chamber B13 can be controlled to so as to be under a reduced pressure or an inert gas atmosphere.

The transfer chamber TF14 is connected to the loadlock chamber B13 through a gate valve. The transfer chamber TF14 is also connected to the unload chamber ULD through another gate valve. The transfer chamber TF14 is provided with the carrying device 70k. The carrying device 70k can carry the substrate into the vacuum process apparatus V from the loadlock chamber B13. In addition, the carrying device 70k can take out the substrate from the vacuum process apparatus V and carry out the substrate to the unload chamber ULD.

With use of the manufacturing equipment having the above structure, highly reliable light-emitting device sealed with a protective film can be formed.

For example, the following steps can be performed successively in the equipment under a controlled atmosphere: a step of forming an organic EL element emitting light of a first color in the clusters C1 to C4; a step of forming an organic EL element emitting light of a second color in the clusters C5 to C8; a step of forming an organic EL element emitting light of a third color in the clusters C9 to C12; a step of removing an unnecessary element in the cluster C13, and a step of forming a protective film in the cluster C14. Details of these steps are described later.

### Structural Example 2

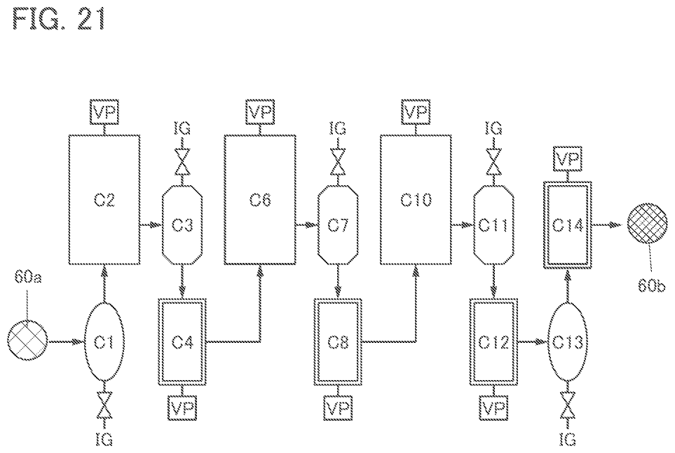

FIG. 21 is a block diagram illustrating manufacturing equipment of a light-emitting device different from that in FIG. 16. The manufacturing equipment in FIG. 21 is an example in which the clusters C1, C2, C3, C4, C6, C7, C8, C10, C11, C12, C13, and C14 are included, which is a structure excluding the clusters C5 and C9 from the manufacturing equipment illustrated in FIG. 16. The clusters C1, C2, C3, C4, C6, C7, C8, C10, C11, C12, C13, and C14 are connected in sequence and the substrate 60a brought into the cluster C1 can be taken out from the cluster C14 as the substrate 60b where light-emitting devices are formed.

In the manufacturing equipment illustrated in FIG. 16, the clusters C5 and C9 each include a cleaning apparatus and a baking apparatus. The steps prior to the cleaning step are an etching (dry etching) and an ashing step. If residual gas components, residues, deposited matters, and the like in these steps do not affect adversely succeeding steps, the cleaning step can be omitted. In the case where the cleaning step is omitted, it is unnecessary to consider residual water in a substrate, and thus the baking step can also be unnecessary. Accordingly, the structure illustrated in FIG. 21 excluding the clusters C5 and C9 from the manufacturing equipment illustrated in FIG. 16 can be employed depending on cases. The total number of the clusters and the loadlock chamber can be reduced by excluding the clusters C5 and C9.

### <Cluster C1 to Cluster C4>

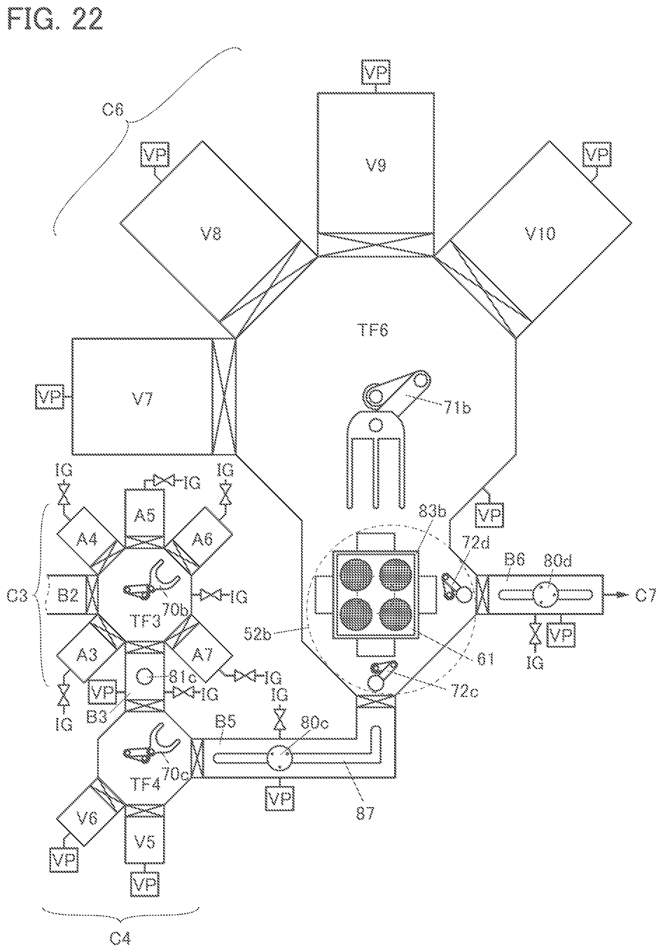

The structures of the cluster C1 to cluster C4 can be similar to those illustrated in FIG. 17 and FIG. 18. The cluster C4 is connected to the cluster C6 through the loadlock chamber B5. In the case where the transfer chamber TF4 is distant from the transfer chamber TF6 in the loadlock chamber B5, the stage 80c may be self-propelled along the rail 87 as illustrated in FIG. 22. Note that the structure in which the stage is self-propelled along the rail can be applied to another stage in the structure example 2, and the description is omitted.

### <Clusters C6, C7, C8, and C10>

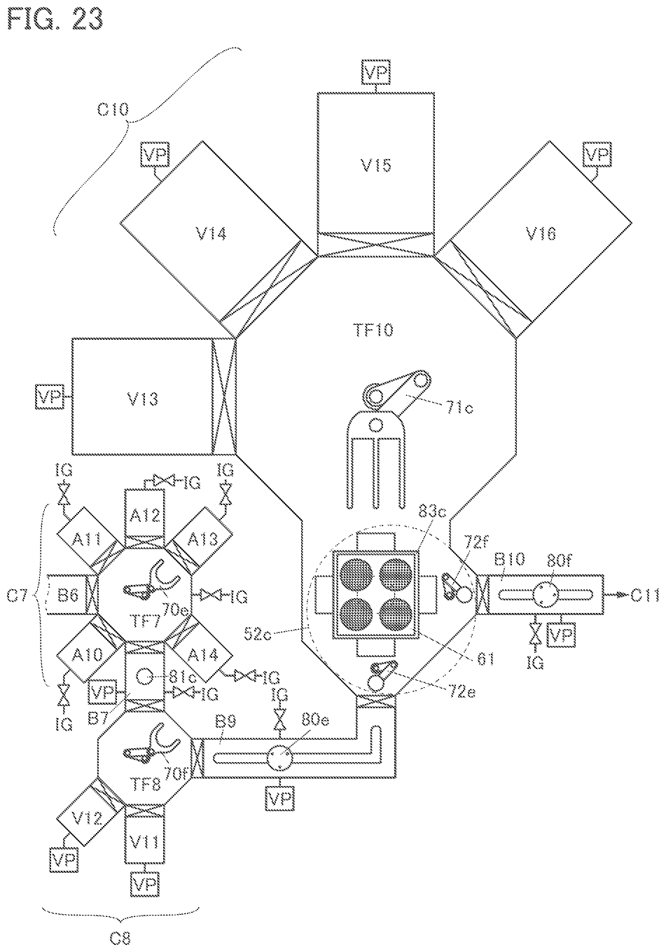

The clusters C6, C7, C8, and C10 are described with reference to FIG. 22 and FIG. 23. The cluster C6 is connected to the cluster C7 through the loadlock chamber B6. The cluster C7 is connected to the cluster C8 through the loadlock chamber B7. The cluster C8 is connected to the cluster C10 through the loadlock chamber B9. The cluster C10 is connected to the cluster C11 (see FIG. 20) through the loadlock chamber B10.

The connections between the clusters are described below. For the details of the clusters and the loadlock chambers, the above description of the clusters C6, C7, C8, and C10 and the loadlock chambers B5, B7, B9, and B10 can be referred to.

The transfer chamber TF6 included in the cluster C6 is connected to the loadlock chamber B5 through a gate valve. The transfer chamber TF6 is also connected to the loadlock chamber B6 through another gate valve. The transfer chamber TF6 is provided with the carrying device 71b and the substrate transfer device 52b.

The substrate transfer device 52b includes the stage 83b and the carrying devices 72c and 72d. The mask jig 61 can be placed on the stage 83b. The carrying device 71b can carry substrates mounted on the mask jig 61 to the vacuum process apparatuses V. Furthermore, the stage 83b can be moved in the X direction, the Y direction, and the θ direction.

The carrying device 72c can reverse the substrate placed in the loadlock chamber B5 and mount the substrate on the mask jig 61. The carrying device 72b can take out the substrate from the mask jig 61, reverse the substrate, and carry out the substrate to the loadlock chamber B6.

The transfer chamber TF7 included in the cluster C7 is connected to the loadlock chamber B6 through a gate valve. The transfer chamber TF7 is also connected to the loadlock chamber B7 through another gate valve. The transfer chamber TF7 is provided with the carrying device 70e. The carrying device 70e can carry the substrate into the normal-pressure process apparatus A from the loadlock chamber B6. The carrying device 70e can also take out the substrate from the normal-pressure process apparatus A, reverse the substrate, and carry out the substrate to the loadlock chamber B7.

The transfer chamber TF8 included in the cluster C8 is connected to the loadlock chamber B7 through a gate valve. The transfer chamber TF8 is also connected to the loadlock chamber B9 through another gate valve. The transfer chamber TF8 is provided with the carrying device 70f The carrying device 70f can carry the substrate into the vacuum process apparatus V from the loadlock chamber B7. The carrying device 70f can also take out the substrate from the vacuum process apparatus V and carry out the substrate to the loadlock chamber B9.

The transfer chamber TF10 included in the cluster C10 is connected to the loadlock chamber B9 through a gate valve. The transfer chamber TF10 is also connected to the loadlock chamber B10 through another gate valve. The transfer chamber TF10 is provided with the carrying device 71c and the substrate transfer device 52c.

The substrate transfer device 52c includes the stage 83c and the carrying devices 72e and 72f The mask jig 61 can be placed on the stage 83b. The carrying device 71c can carry substrates mounted on the mask jig 61 into the vacuum process apparatuses V. Furthermore, the stage 83c can be moved in the X direction, the Y direction, and the θ direction.

The carrying device 72e can reverse the substrate placed in the loadlock chamber B9 and mount the substrate on the mask jig 61. The carrying device 72f can take out the substrate from the mask jig 61, reverse the substrate, and carry out the substrate to the loadlock chamber B10.

### <Clusters C11, C12, C13, and C14>

The structures of the cluster C11 to the cluster C14 can be similar to the structures illustrated in FIG. 20.

### <Substrate-Carrying Operation>

For an operation and the like for carrying a substrate from the cluster C1 to the cluster C2, descriptions of FIG. 12 and FIG. 13 in Embodiment 1 can be referred to.

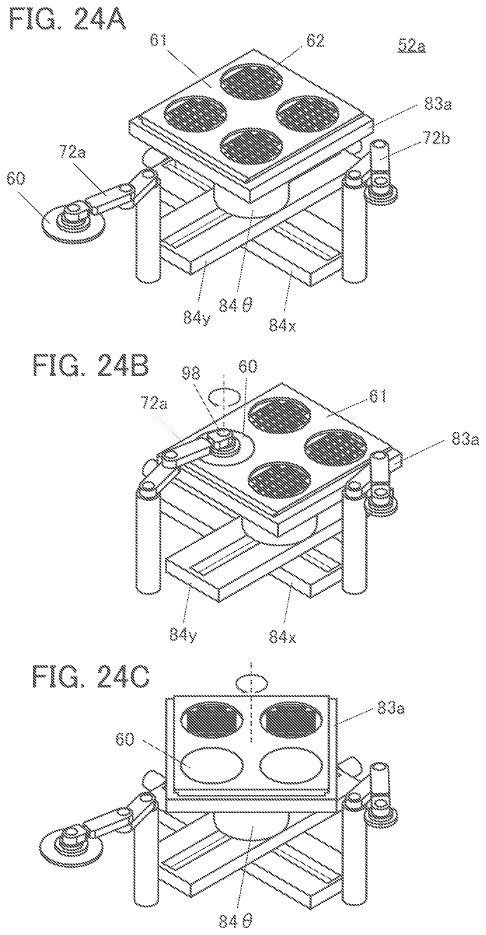

FIG. 24A is a diagram illustrating the substrate transfer device 52a included in the cluster C2. The substrate transfer device 52a includes the carrying device 72a, the stage 83a, and the carrying device 72b. Note that chamber walls, gate valves, and the like are not illustrated for the sake of clarity. The substrate transfer device 52b and the substrate transfer device 52c having a structure similar to that of the substrate transfer device 52a can work as in the description below.

The structure of the carrying device 72a is as described above. The carrying device 72b also has a similar structure.

The stage 83a is fixed on a plurality of moving mechanisms. As illustrated in FIG. 24A, the movement mechanism can be, for example, a combination of an X-axis moving mechanism 84x, a Y-axis moving mechanism 84y, and a θ-axis moving mechanism 84θ, for example. The Y-axis moving mechanism 84y is fixed on the X-axis moving mechanism 84x, the θ-axis moving mechanism 84θ is fixed on the Y-axis moving mechanism 84, the stage 83a is fixed on the θ-axis moving mechanism 84θ, and thus the stage 83a can move in a certain range of each of the X-axis direction, the Y-axis direction, and the θ-axis direction.

By adjusting the movement range of the stage 83a and the expansion and contraction of the arms of the carrying devices 72a and 72b, the substrate 60 can be mounted on an upper depression portion 62 of the mask jig 61 placed on the stage 83a. Note that the mask jig 61 includes an opening portion and a lower depression portion in addition to the upper depression portion 62. The details will be described later.

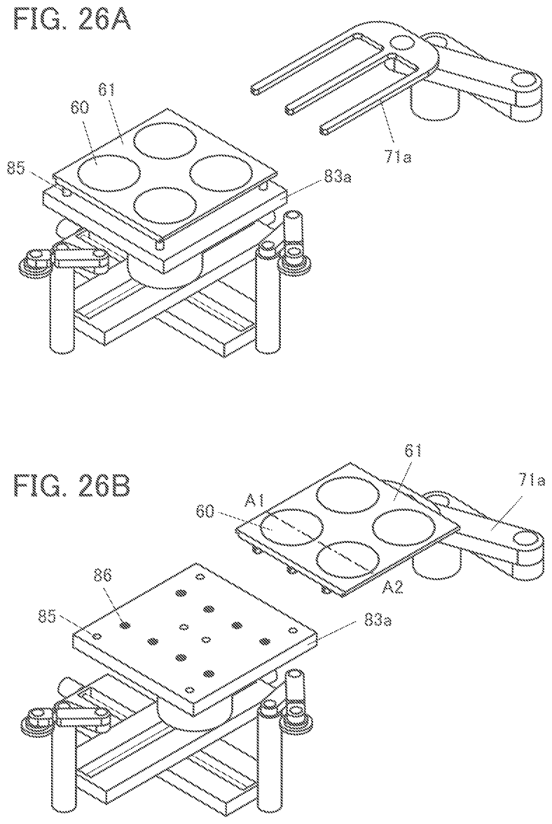

The carrying device 72a includes a substrate rotating mechanism 98 that rotates the substrate fixing portion 96. A circuit and the like are provided on the surface of the substrate 60 in advance, and the substrate 60 is attached closely to the mask jig 61 so as to avoid deposition in an unnecessary area. Thus, when the substrate 60 is mounted on the mask jig 61, a pattern provided in advance in the substrate 60 is aligned in the θ-direction with the opening portion in the mask jig 61 with use of the substrate rotation mechanism 98 (see FIG. 24B). Note that a camera 86 used for the alignment can be provided in the stage 83a (see FIG. 26B).

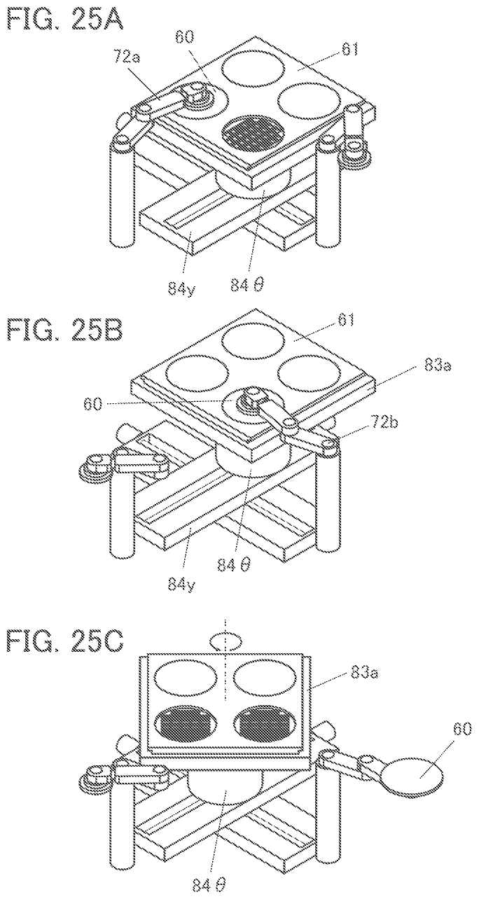

The size of the mask jig 61 and the number of substrates 60 mounted may be determined depending on the purpose. In the case where the length of the arm of the carrying device 72a is insufficient, the stage 83a may be rotated by the θ-axis moving mechanism 84θ to make the mount position of the substrates 60 close to the carrying device 72a (see FIG. 24C and FIG. 25A). Note that in the case where the length of the arm of the carrying device 72a is sufficiently long, the θ-axis moving mechanism 84θ is not necessarily provided. Furthermore, the X-axis moving mechanism 84x and the Y-axis moving mechanism 84y can be unnecessary.

After a desired number of substrates 60 are placed in the mask jig 61 with the carrying device 72a, a deposition step is performed in the cluster C2. After that, the mask jig 61 is put back on the stage 83a. The substrate 60 on which the deposition step has been performed is taken out from the mask jig 61 with the carrying device 72b (see FIG. 25B). In addition, since the next step is a lithography step in the cluster C3 including the carrying device 70b, the substrate is reversed by the carrying device 72b (see FIG. 25C).

Carrying into the vacuum process apparatus V where a deposition step is performed is conducted with use of the carrying device 71a in the cluster C2 (see FIG. 26A).

The carrying device 71a includes a lifting mechanism, an arm, and a hand portion. The stage 83a is provided with pusher pins 85. The mask jig 61 is raised with the pusher pins 85, the hand portion of the carrying device 71a is inserted between the stage 83a and the mask jig 61, and the pusher pins 85 are lowered or the hand portion is raised, so that the mask jig 61 can be placed on the hand portion (see FIG. 26B).

Note that the stage 83a is provided with the camera 86 in addition to the pusher pins 85. The camera 86 is provided at a position overlapping with the opening portion of the mask jig 61. Thus, an alignment operation can be performed while the opening portion of the mask jig 61 and the pattern provided in the substrate 60 are viewed with the camera 86.

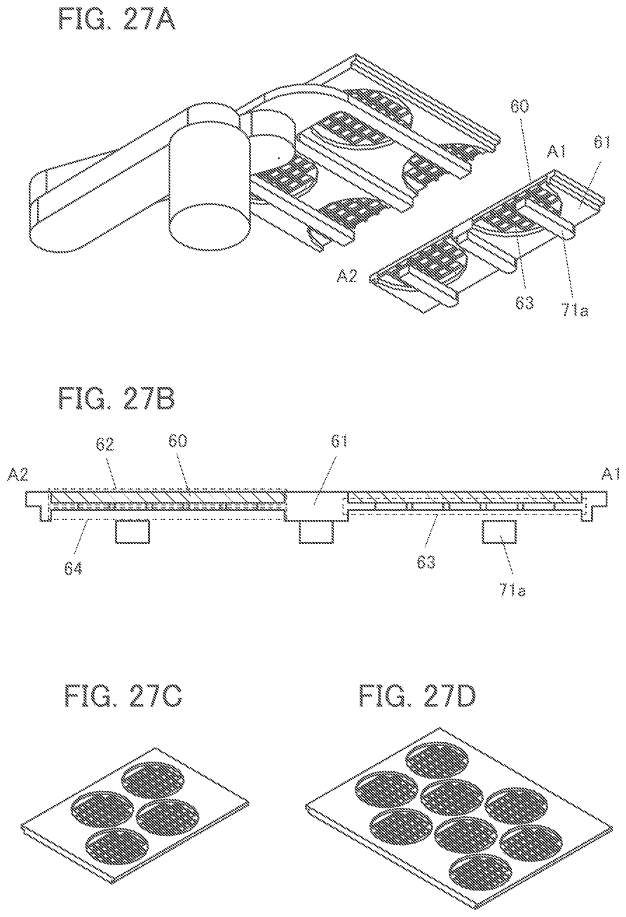

FIG. 27A is a cross-sectional perspective view where the mask jig 61 is placed on the hand portion of the carrying device 71a, which is separated along the line A1-A2 (see FIG. 26B). FIG. 27B is a cross-sectional view of only the mask jig 61.

The mask jig 61 includes the upper depression portion 62 where the substrate 60 is to be mounted, the lower depression portion 64, and the opening portion 63. The lower depression portion 64 allows the hand portion of the carrying device 71a to be in contact with the outside of the lower depression portion 64 and not to be in contact with the vicinity of the opening portion 63. Therefore, a certain distance can be kept between the hand portion and the surface (deposition surface) of the substrate 60, thereby inhibiting contamination of the substrate 60, attachment of dusts to the substrate 60, or the like caused from the hand portion.

The example of the mask jig 61 in which four substrates 60 are mounted at even intervals is described here; however, the substrates 60 may be placed in a staggered array as illustrated in FIG. 27C. Alternatively, as illustrated in FIG. 27D, more substrates 60 may be mounted. With the staggered array, the size of the mask jig 61 can be reduced, leading to a reduction in the size of the deposition apparatus or the like, and further a reduction in the area of the whole manufacturing equipment.

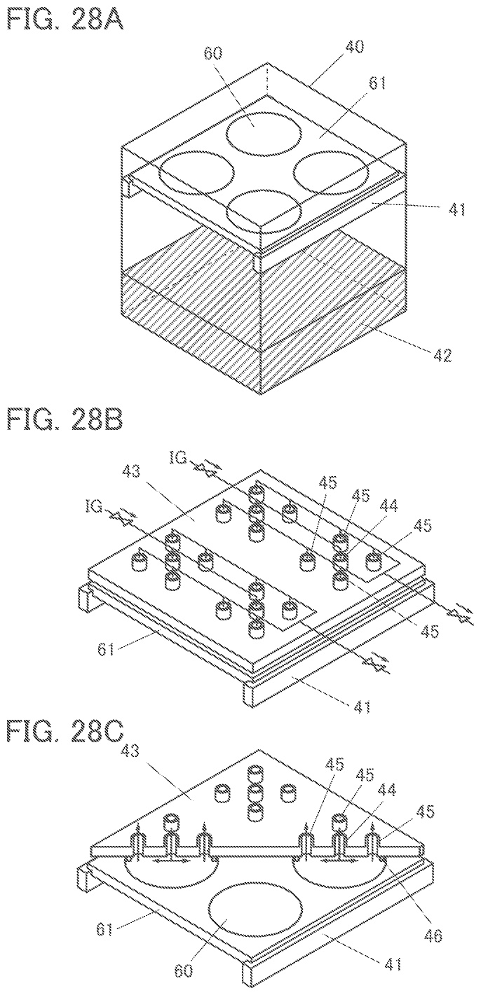

FIG. 28A is a diagram illustrating the vacuum process apparatus V in which the mask jig 61 is placed, and a deposition apparatus 40 is illustrated here as an example. Note that for the sake of clarity, a chamber wall is illustrated as a transparent view and a gate valve is not illustrated in the diagram.

The deposition apparatus 40 includes a deposition material supply unit 42 and a rail 41 on which the mask jig 61 is to be placed. The deposition material supply unit 42 is provided with an evaporation source when the deposition apparatus 40 is an evaporation apparatus. In addition, the deposition material supply unit 42 is provided with a target (cathode) when the deposition apparatus 40 is a sputtering apparatus.

The rail 41 is fixed in the chamber, and a cutout portion of the mask jig 61 is put on the rail 41, whereby the mask jig 61 can be stably placed. The rail 41 is provided at the position where the deposition material supply unit 42 faces the mask jig 61.

Note that a cooling plate 43 illustrated in FIG. 28B may be provided over the mask jig 61. The cooling plate 43 is provided with an inlet port 44 and an outlet port 45 for a gas to cool down the substrate 60. FIG. 28C is a diagram illustrating the cooling plate 43 part of which is cut out. The substrate 60 is in contact with a sealant 46 (e.g., an O-ring) provided in the cooling plate 43. Therefore, a closed space with the sealant 46 as a sidewall is formed between the substrate 60 and the cooling plate.

A cooling gas (such as an inert gas) is introduced into the closed space through the inlet port 44, and the cooling gas to which heat is transferred from the substrate 60 can be exhausted from the outlet port 45. Note that a conductance valve is provided for one or both of the inlet port 44 and the outlet port 45, and introduction and exhaust of the cooling gas are performed while the closed space is kept under a constant pressure, whereby the substrate 60 can be cooled uniformly.

Although FIG. 28B illustrates an example in which one valve is provided for each of the inlet port 44 and the outlet ports 45 in a two-system, one valve may be provided for each of the inlet port 44 and the outlet ports 45 in a one-system. Note that the numbers of the inlet ports 44 and the outlet ports 45 are not limited and can be determined in consideration of cooling ability and cooling uniformity.

Since high temperatures change properties of organic compounds included in an organic EL element or the like, steps after the formation of an organic compound are preferably performed at 80° C. or lower, further preferably 70° C. or lower. In a sputtering apparatus, the substrate 60 is exposed to plasma; thus, the substrate 60 is sometimes heated to 100° C. or higher. Therefore, the substrate 60 is preferably cooled down using the above-described cooling plate 43. Note that the expression “cooled down” is used above; however, it can be also said that the temperature of the substrate is adjusted to a certain temperature or lower.

This embodiment can be implemented in an appropriate combination with the structures described in the other embodiments.

### Embodiment 3

This embodiment will describe a specific example for manufacturing a light-emitting element (organic EL element) with the use of manufacturing equipment of a light-emitting device that is one embodiment of the present invention.

In this specification and the like, a device formed using a metal mask or an FMM (fine metal mask or high-resolution metal mask) is sometimes referred to as a device having an MM (metal mask) structure. In this specification and the like, a device formed without using a metal mask or an FMM may be referred to as a device having an MML (metal maskless) structure.

In this specification and the like, a structure in which light-emitting layers in light-emitting devices of different colors (here, blue (B), green (G), and red (R)) are separately formed or separately patterned is sometimes referred to as an SBS (Side By Side) structure. In this specification and the like, a light-emitting device capable of emitting white light may be referred to as a white-light-emitting device. Note that a white-light-emitting device that is combined with coloring layers (e.g., color filters) can be a light-emitting device of full-color display.

Structures of light-emitting devices can be classified roughly into a single structure and a tandem structure. A device having a single structure includes one light-emitting unit between a pair of electrodes, and the light-emitting unit preferably includes one or more light-emitting layers. To obtain white light emission, two or more light-emitting layers are selected such that emission colors of the light-emitting layers are complementary colors. For example, when emission colors of a first light-emitting layer and a second light-emitting layer are complementary colors, the light-emitting device can be configured to emit white light as a whole. The same applies to a light-emitting device including three or more light-emitting layers.

A device having a tandem structure includes two or more light-emitting units between a pair of electrodes, and each light-emitting unit preferably includes one or more light-emitting layers. To obtain white light emission, the structure is made so that light from light-emitting layers of the plurality of light-emitting units can be combined to be white light. Note that a structure for obtaining white light emission is similar to a structure in the case of a single structure. In the device having a tandem structure, it is suitable that an intermediate layer such as a charge-generation layer is provided between a plurality of light-emitting units.

When the white-light-emitting device (having a single structure or a tandem structure) and a light-emitting device having an SBS structure are compared to each other, the light-emitting device having an SBS structure can have lower power consumption than the white-light-emitting device. To reduce power consumption, a light-emitting device having an SBS structure is preferably used. Meanwhile, the white-light-emitting device is preferable in terms of lower manufacturing cost or higher manufacturing yield because the manufacturing process of the white-light-emitting device is simpler than that of a light-emitting device having an SBS structure.

The device with a tandem structure may include light-emitting layers emitting light of the same color (e.g., BB, GG, or RR). The tandem structure emitting light from a plurality of layers requires high voltage for light emission but achieves the same emission intensity as a single structure with a smaller current value. Thus, with the tandem structure, current stress on each light-emitting unit can be reduced and the element lifetime can be extended.

### Structure Example

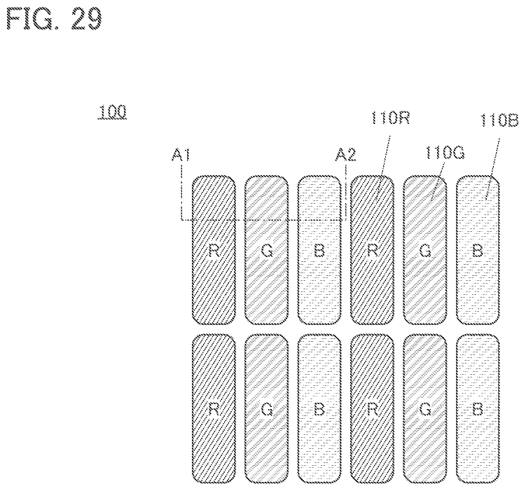

FIG. 29 is a schematic top view of a display device 100 fabricated using manufacturing equipment for a light-emitting device of one embodiment of the present invention. The display device 100 includes a plurality of light-emitting elements 110R exhibiting red, a plurality of light-emitting elements 110G exhibiting green, and a plurality of light-emitting elements 110B exhibiting blue. In FIG. 29, light-emitting regions of the light-emitting elements are denoted by R, G, and B to easily differentiate the light-emitting elements.

The light-emitting elements 110R, the light-emitting elements 110G, and the light-emitting elements 110B are arranged in a matrix. FIG. 29 illustrates what is called a stripe arrangement, in which the light-emitting elements of the same color are arranged in one direction. Note that the arrangement method of the light-emitting elements is not limited thereto; another arrangement method such as a delta arrangement, a zigzag arrangement, or a PenTile arrangement may also be used.

As each of the light-emitting elements 110R, the light-emitting elements 110G, and the light-emitting elements 110B, an EL element such as an OLED (Organic Light Emitting Diode) or a QLED (Quantum-dot Light Emitting Diode) is preferably used. As a light-emitting substance contained in the EL element, a substance that emits fluorescent light (a fluorescent material), a substance that emits phosphorescent light (a phosphorescent material), an inorganic compound (e.g., a quantum dot material), a substance that exhibits thermally activated delayed fluorescence (a thermally activated delayed fluorescent (TADF) material), and the like can be given.

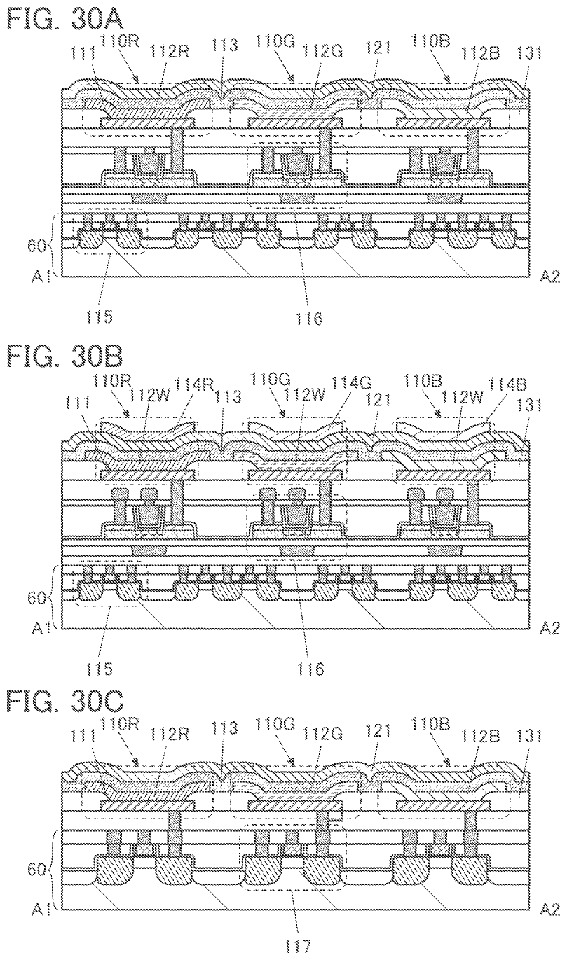

FIG. 30A is a cross-sectional schematic view taken along dashed-dotted line A1-A2 in FIG. 29.

FIG. 30A illustrates cross sections of the light-emitting element 110R, the light-emitting element 110G, and the light-emitting element 110B. The light-emitting element 110R, the light-emitting element 110G, and the light-emitting element 110B are provided over a pixel circuit and each include a pixel electrode 111 and a common electrode 113.

The light-emitting element 110R includes an EL layer 112R between the pixel electrode 111 and the common electrode 113. The EL layer 112R contains at least a light-emitting organic compound that emits light having a peak in the red wavelength range. An EL layer 112G included in the light-emitting element 110G contains at least a light-emitting organic compound that emits light having a peak in the green wavelength range. An EL layer 112B included in the light-emitting element 110B contains at least a light-emitting organic compound that emits light having a peak in the blue wavelength range. Note that a structure in which the EL layer 112R, the EL layer 112G, and the EL layer 112B emit light of different colors may be referred to as an SBS (Side By Side) structure.

The EL layer 112R, the EL layer 112G, and the EL layer 112B may each include one or more of an electron-injection layer, an electron-transport layer, a hole-injection layer, and a hole-transport layer in addition to the layer containing a light-emitting organic compound (light-emitting layer).

The pixel electrode 111 is provided in each of the light-emitting elements. The common electrode 113 is provided as a continuous layer shared by the light-emitting elements. A conductive film with a property of transmitting visible light is used for either one of the pixel electrode 111 and the common electrode 113, and a conductive film with a property of reflecting visible light is used for the other. When the pixel electrodes 111 are light-transmitting electrodes and the common electrode 113 is a reflective electrode, a bottom-emission display device is obtained; in contrast, when the respective pixel electrodes 111 are reflective electrodes and the common electrode 113 is a light-transmitting electrode, a top-emission display device is obtained. Note that when both the pixel electrode 111 and the common electrode 113 have a light-transmitting property, the display device can have a dual emission structure. In this embodiment, an example of manufacturing a top-emission display device having a top-emission structure is described.

An insulating layer 131 is provided to cover end portions of the pixel electrode 111. The end portion of the insulating layer 131 is preferably tapered.

The EL layer 112R, the EL layer 112G, and the EL layer 112B each include a region in contact with the top surface of the pixel electrode 111 and a region in contact with a surface of the insulating layer 131. End portions of the EL layer 112R, the EL layer 112G, and the EL layer 112B are positioned over the insulating layer 131.

As illustrated in FIG. 30A, there is a gap between the two EL layers of the light-emitting elements with different colors. In this manner, the EL layer 112R, the EL layer 112G, and the EL layer 112B are preferably provided so as not to be in contact with each other. This can suitably prevent unintended light emission from being caused by a current flowing through two adjacent EL layers. As a result, the contrast can be increased, so that a display apparatus with high display quality can be achieved.

A protective layer 121 is provided over the common electrode 113 so as to cover the light-emitting element 110R, the light-emitting element 110G, and the light-emitting element 110B. The protective layer 121 has a function of preventing diffusion of impurities into the light-emitting elements from above. Alternatively, the protective layer 121 has a function of capturing (also called gettering) impurities (such as water and hydrogen typically) that may enter the light-emitting elements.

The protective layer 121 can have, for example, a single-layer structure or a stacked-layer structure at least including an inorganic insulating film. As the inorganic insulating film, for example, an oxide film or a nitride film such as a silicon oxide film, a silicon oxynitride film, a silicon nitride oxide film, a silicon nitride film, an aluminum oxide film, an aluminum oxynitride film, or a hafnium oxide film can be given. Alternatively, a semiconductor material such as indium gallium oxide or indium gallium zinc oxide may be used for the protective layer 121.

The pixel electrode 111 is electrically connected to one of a source and a drain of a transistor 116. A transistor including a metal oxide in a channel formation region (hereinafter, an OS transistor) can be used as the transistor 116, for example. The OS transistor has higher mobility than amorphous silicon and has excellent electrical characteristics. In addition, crystallization needed in the manufacturing process using polycrystalline silicon is not necessary for the OS transistor, and the OS transistor can be fabricated in the back end of line or the like. Therefore, the OS transistor can be formed over a transistor 115 using silicon in a channel formation region formed with the substrate 60 (hereinafter, such a transistor is referred to as Si transistor) without a bonding step.

The transistor 116 is included in a pixel circuit. The transistor 115 is included in a driver circuit for the pixel circuit or the like. In other words, the pixel circuit can be formed over the driver circuit, which enables formation of a display device with a narrow bezel.

As a semiconductor material used for an OS transistor, a metal oxide whose energy gap is greater than or equal to 2 eV, preferably greater than or equal to 2.5 eV, further preferably greater than or equal to 3 eV can be used.

In an OS transistor, a semiconductor layer has a large energy gap, and thus the OS transistor has an extremely low off-state current of several yoctoamperes per micrometer (current per micrometer of a channel width). An OS transistor has features such that impact ionization, an avalanche breakdown, a short-channel effect, or the like does not occur, which are different from those of a Si transistor. Thus, the use of an OS transistor enables formation of a circuit having high withstand voltage and high reliability. Moreover, variation in electrical characteristics due to crystallinity unevenness, which is caused in Si transistors, is less likely to occur in OS transistors.

A semiconductor layer in an OS transistor can be, for example, a film represented by an In-M-Zn-based oxide that contains indium, zinc, and M (one or more of metals such as aluminum, titanium, gallium, germanium, yttrium, zirconium, lanthanum, cerium, tin, neodymium, and hafnium). The In-M-Zn-based oxide can be typically formed by a sputtering method. Alternatively, the In-M-Zn-based oxide can be formed by an ALD (Atomic layer deposition) method.

It is preferable that the atomic ratio of metal elements in a sputtering target used to form an In-M-Zn oxide by a sputtering method satisfy In≥M and Zn≥M. The atomic ratio of metal elements in such a sputtering target is preferably, for example, In:M:Zn=1:1:1, In:M:Zn=1:1:1.2, In:M:Zn=3:1:2, In:M:Zn=4:2:3, In:M:Zn=4:2:4.1, In:M:Zn=5:1:6, In:M:Zn=5:1:7, or In:M:Zn=5:1:8. Note that the atomic ratio in the formed semiconductor layer varies from the above atomic ratio of metal elements of the sputtering target in a range of ±40%.

An oxide semiconductor with low carrier density is used for the semiconductor layer. For example, for the semiconductor layer, an oxide semiconductor whose carrier density is lower than or equal to 1×10¹⁷/cm³, preferably lower than or equal to 1×10¹⁵/cm³, further preferably lower than or equal to 1×10¹³/cm³, still further preferably lower than or equal to 1×10¹¹/cm³, even further preferably lower than 1×10¹⁰/cm³, and higher than or equal to 1×10⁻⁹/cm³ can be used. Such an oxide semiconductor is referred to as a highly purified intrinsic or substantially highly purified intrinsic oxide semiconductor. The oxide semiconductor has a low density of defect states and can thus be referred to as an oxide semiconductor having stable characteristics.

Note that the composition is not limited to those described above, and an oxide semiconductor having an appropriate composition can be used depending on required semiconductor characteristics and electrical characteristics (e.g., field-effect mobility and threshold voltage) of the transistor. To obtain the required semiconductor characteristics of the transistor, it is preferable that the carrier density, the impurity concentration, the defect density, the atomic ratio between a metal element and oxygen, the interatomic distance, the density, and the like of the semiconductor layer be set to appropriate values.

Although FIG. 30A illustrates an exemplary structure in which the light-emitting layers of the R, G, and B light-emitting elements are different from each other, one embodiment of the present invention is not limited thereto. For example, as illustrated in FIG. 30B, a coloring method may be employed in which the light-emitting elements 110R, 110G, and 110B are formed by providing EL layers 112W that emit white light and providing coloring layers 114R (red), 114G (green), and 114B (blue) that overlap with the EL layers 112W.

The EL layer 112W can have a tandem structure in which EL layers emitting R, G, and B light are connected in series, for example. Alternatively, a structure in which light-emitting layers emitting R, G, and B light are connected in series may be used. As the coloring layers 114R, 114G, and 114B, for example, red, green, and blue color filters can be used.

As illustrated in FIG. 30C, a pixel circuit may be formed with a transistor 117 included in the substrate 60, and one of a source and a drain of the transistor 117 may be electrically connected to the pixel electrode 111.

### Example of Manufacturing Method

An example of a manufacturing method of a light-emitting device with manufacturing equipment of one embodiment of the present invention, will be described below. Here, description is made using an example of the light-emitting device included in the display device 100 described in the above structure example.

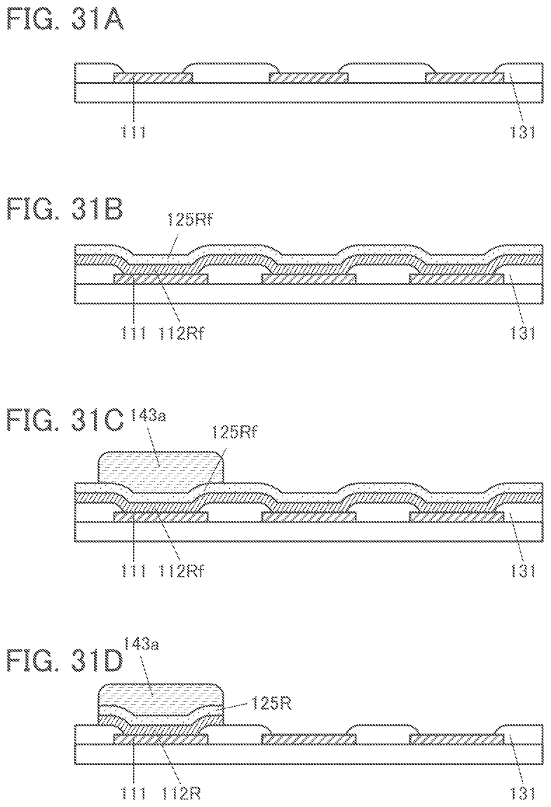

FIG. 31A to FIG. 31E are schematic cross-sectional views in steps of the manufacturing method of the light-emitting device described below. Note that the transistor 116 that is a component of the pixel circuit and the transistor 115 that is a component of the driver circuit, which are illustrated in FIG. 30A, are omitted in FIG. 31A to FIG. 33E.

Note that thin films constituting the display device (insulating films, semiconductor films, conductive films, and the like) can be formed by a sputtering method, a chemical vapor deposition (CVD) method, a vacuum evaporation method, an atomic layer deposition (ALD) method, or the like. Examples of the CVD method include a plasma-enhanced chemical vapor deposition (PECVD: Plasma Enhanced CVD) method and a thermal CVD method. An example of a thermal CVD method is a metal organic chemical vapor deposition (MOCVD: Metal Organic CVD) method. The manufacturing equipment of one embodiment of the present invention can include an apparatus for forming thin films by the above method.

A method such as spin coating, dipping, spray coating, ink-jetting, dispensing, screen printing, offset printing, a doctor knife method, slit coating, roll coating, curtain coating, or knife coating can be employed for formation of the thin films constituting the display device (insulating films, semiconductor films, conductive films, and the like) and application of a resin or the like used for a lithography step. The manufacturing equipment of one embodiment of the present invention can include an apparatus for forming thin films by the above method. In addition, the manufacturing equipment of one embodiment of the present invention can include an apparatus for applying a resin by the above method.

The thin films constituting the display device can be processed by a photolithography method or the like. Alternatively, the thin films may be processed by a nanoimprinting method. A method in which island-shaped thin films are directly formed by a deposition method using a blocking mask may also be used.

There are two typical methods for processing a thin film using a photolithography method. In one of the methods, a resist mask is formed over a thin film that is to be processed, the thin film is processed by etching or the like, and then the resist mask is removed. In the other method, a photosensitive thin film is deposited and then processed into a desired shape by light exposure and development.

As light for exposure in a photolithography method, it is possible to use light with the i-line (wavelength: 365 nm), light with the g-line (wavelength: 436 nm), light with the h-line (wavelength: 405 nm), or combined light of any of them. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Furthermore, instead of the light used for the exposure, an electron beam can also be used. It is preferable to use extreme ultraviolet light, X-rays, or an electron beam because extremely minute processing can be performed. Note that a photomask is not needed when exposure is performed by scanning with a beam such as an electron beam.

For etching of thin films, a dry etching method, a wet etching method, or the like can be used. The manufacturing equipment of one embodiment of the present invention can include an apparatus for processing thin films by the above method.

### <Preparation of Substrate 60>

As the substrate 60, a substrate having at least heat resistance high enough to withstand later heat treatment can be used. In the case where an insulating substrate is used as the substrate 60, a glass substrate, a quartz substrate, a sapphire substrate, a ceramics substrate, an organic resin substrate, or the like can be used. Alternatively, a single crystal semiconductor substrate using silicon or silicon carbide, a polycrystalline semiconductor substrate, a compound semiconductor substrate of silicon germanium or the like, a semiconductor substrate such as an SOI substrate, or the like can be used.

As the substrate 60, it is particularly preferable to use the semiconductor substrate or the insulating substrate over which a semiconductor circuit including a semiconductor element such as a transistor is formed. With the semiconductor circuit, a pixel circuit, a gate line driver circuit (a gate driver), a source line driver circuit (a source driver), or the like is preferably formed. In addition to the above, an arithmetic circuit, a memory circuit, or the like may be formed.

### <Formation of Pixel Circuit and Pixel Electrode 111>

Next, a plurality of pixel circuits are formed over the substrate 60, and the pixel electrode 111 is formed for each of the pixel circuits. First, a conductive film to be the pixel electrodes 111 is formed, a resist mask is formed by a photolithography method, and an unnecessary portion of the conductive film is removed by etching. After that, the resist mask is removed, so that the pixel electrodes 111 can be formed.

It is preferable to use, for the pixel electrodes 111, a material (e.g., silver or aluminum) having reflectance as high as possible in the whole wavelength range of visible light. The pixel electrodes 111 formed using the material can be referred to as electrodes having a light-reflecting property. This can increase color reproducibility as well as light extraction efficiency of the light-emitting elements.

### <Formation of Insulating Layer 131>

Subsequently, the insulating layer 131 is formed to cover end portions of the pixel electrodes 111 (see FIG. 31A). An organic insulating film or an inorganic insulating film can be used for the insulating layer 131. The end portion of the insulating layer 131 is preferably tapered to improve step coverage with an EL film formed later. In particular, when an organic insulating film is used, a photosensitive material is preferably used so that the shape of the end portions can be easily controlled by the conditions of light exposure and development.

### <Formation of EL Film 112Rf>

Subsequently, an EL film 112Rf to be the EL layer 112R later is formed over the pixel electrodes 111 and the insulating layer 131.

The EL film 112Rf includes at least a film containing a red-light-emitting organic compound. A structure may be employed in which an electron-injection layer, an electron-transport layer, a charge-generation layer, a hole-transport layer, and a hole-injection layer are stacked in addition to the above. The EL film 112Rf can be formed by an evaporation method or a sputtering method, for example. Without limitation to this, the above-described deposition method can be used as appropriate.

### <Formation of Protective Film 125Rf>

Next, a protective film 125Rf to be a protective layer 125R later is formed over the EL film 112Rf (see FIG. 31B).

The protective layer 125R is a tentative protective layer, which is also called a sacrifice layer, used for preventing the EL layer 112R from being degraded and vanishing in a manufacturing process of the organic EL elements. The protective films 125Rf is preferably formed by a deposition method that has high barrier property against moisture or the like and is less likely to give damage to an organic compound during deposition. Furthermore, the protective film 125Rf is preferably formed using a material for which an etchant less likely to give damage to the organic compound in an etching step is acceptable. The protective film 125Rf can be formed using an inorganic film such as a metal film, an alloy film, a metal oxide film, a semiconductor film, or an inorganic insulating film, for example.

<Formation of Resist Mask 143a>

Next, a resist mask 143a is formed over the pixel electrode 111 corresponding to the light-emitting element 110R (see FIG. 31C). The resist mask 143a can be formed by a lithography step.

### <Formation of EL Layer 112R and Protective Layer 125R>

Then, the protective film 125Rf and the EL film 112Rf are etched with the resist mask 143a serving as a mask, so that the protective layer 125R and the EL layer 112R are formed to have an island shape (see FIG. 31D). A dry etching method or a wet etching method can be used for the etching step. After that, the resist mask 143a is removed by ashing or using a resist stripper.

### <Formation of EL Film 112Gf>

Subsequently, an EL film 112Gf to be the EL layer 112G later is formed over the exposed pixel electrodes 111 and insulating layer 131, and the protective layer 125R.

The EL film 112Gf includes at least a film containing a green-light-emitting organic compound. A structure may be employed in which an electron-injection layer, an electron-transport layer, a charge-generation layer, a hole-transport layer, and a hole-injection layer are stacked in addition to the above.

### <Formation of Protective Film 125Gf>

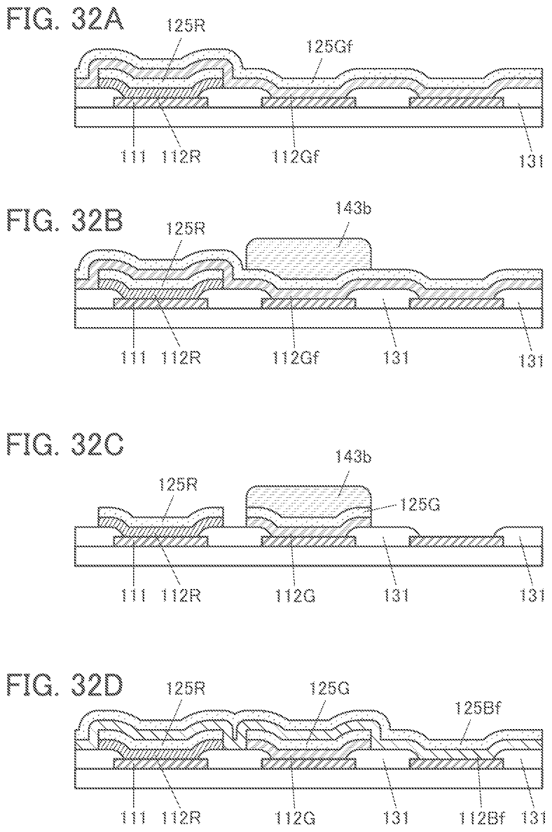

Then, a protective film 125Gf to be a protective layer 125G later is formed over the EL film 112Gf (see FIG. 32A). The protective film 125Gf can be formed using a material similar to that of the protective film 125Rf.

<Formation of Resist Mask 143b>

Next, a resist mask 143b is formed over the pixel electrode 111 corresponding to the light-emitting element 110G (see FIG. 32B). The resist mask 143b can be formed by a lithography step.

### <Formation of EL Layer 112G and Protective Layer 125G>

Then, the protective film 125Gf and the EL film 112Gf are etched with the resist mask 143b as a mask, so that the protective layer 125G and the EL layer 112G are formed to have an island shape (see FIG. 32C). A dry etching method or a wet etching method can be used for the etching step. After that, the resist mask 143b is removed by ashing or using a resist stripper.

### <Formation of EL Film 112Bf>

Subsequently, an EL film 112Bf to be the EL layer 112B later is formed over the exposed pixel electrode 111 and insulating layer 131, and the protective layers 125R and 125G.

The EL film 112Bf includes at least a film containing a blue-light-emitting organic compound. A structure may be employed in which an electron-injection layer, an electron-transport layer, a charge-generation layer, a hole-transport layer, and a hole-injection layer are stacked in addition to the above.

### <Formation of Protective Film 125Bf>

Next, a protective film 125Bf to be a protective layer 125B later is formed over the EL film 112Bf (see FIG. 32D). The protective film 125Bf can be formed using a material similar to that of the protective film 125Rf.

<Formation of Resist Mask 143c>

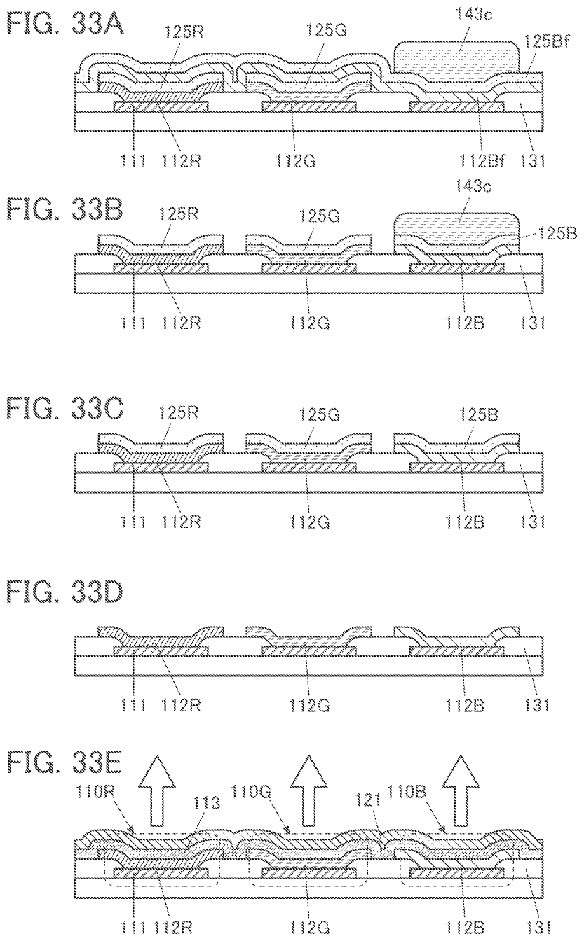

Next, a resist mask 143c is formed over the pixel electrode 111 corresponding to the light-emitting element 110B (see FIG. 33A). The resist mask 143b can be formed by a lithography step.

### <Formation of EL Layer 112B and Protective Layer 125B>

Then, the protective film 125Bf and the EL film 112Bf are etched with the resist mask 143c as a mask, so that the protective layer 125B and the EL layer 112G are formed to have an island shape (see FIG. 33B). A dry etching method or a wet etching method can be used for the etching step. After that, the resist mask 143b is removed by ashing or using a resist stripper (see FIG. 33C).

### <Removal of Protective Layers 125R, 125G, and 125B>

Next, the protective layers 125R, 125G, and 125B are removed (see FIG. 33D). A wet etching method using an etchant suitable for the material of the protective layers is preferably used for the removal of the protective layers, for example.

### <Formation of Common Electrode>

Then, a conductive layer to be the common electrode 113 of the organic EL elements is formed over the EL layer 112R, the EL layer 112G, and the EL layer 112B that are exposed in the previous step and the insulating layer 131. In the case where a top emission display device is manufactured, for the common electrode 113, either one of a thin metal film that transmits light emitted from the light-emitting layer (e.g., an alloy of silver and magnesium) and a light-transmitting conductive film (e.g., indium tin oxide or an oxide containing one or more of indium, gallium, zinc, and the like) or a stack of these films can be used. The common electrode 113 formed using such a film can be referred to as an electrode having a light-transmitting property. For the step of forming the conductive layer to be the common electrode 113, an evaporation apparatus and/or a sputtering apparatus can be used, for example.

Note that before the formation of the common electrode 113, a layer having a function of any of an electron-injection layer, an electron-transport layer, a charge-generation layer, a hole-transport layer, and a hole-injection layer may be provided as a common layer over the EL layer 112R, the EL layer 112G, and the EL layer 112B, so that the reliability is improved.

When the electrodes having a light-reflecting property are included as the pixel electrodes 111 and the electrode having a light-transmitting property is included as the common electrode 113, light emitted from the light-emitting layers can be emitted to the outside through the common electrode 113. In other words, top emission light-emitting elements are formed.

### <Formation of Protective Layer>

Next, the protective layer 121 is formed over the common electrode 113 (FIG. 33E). A sputtering apparatus, a CVD apparatus, an ALD apparatus, or the like can be used for the step of forming the protective layer.

### Example 1 of Manufacturing Equipment

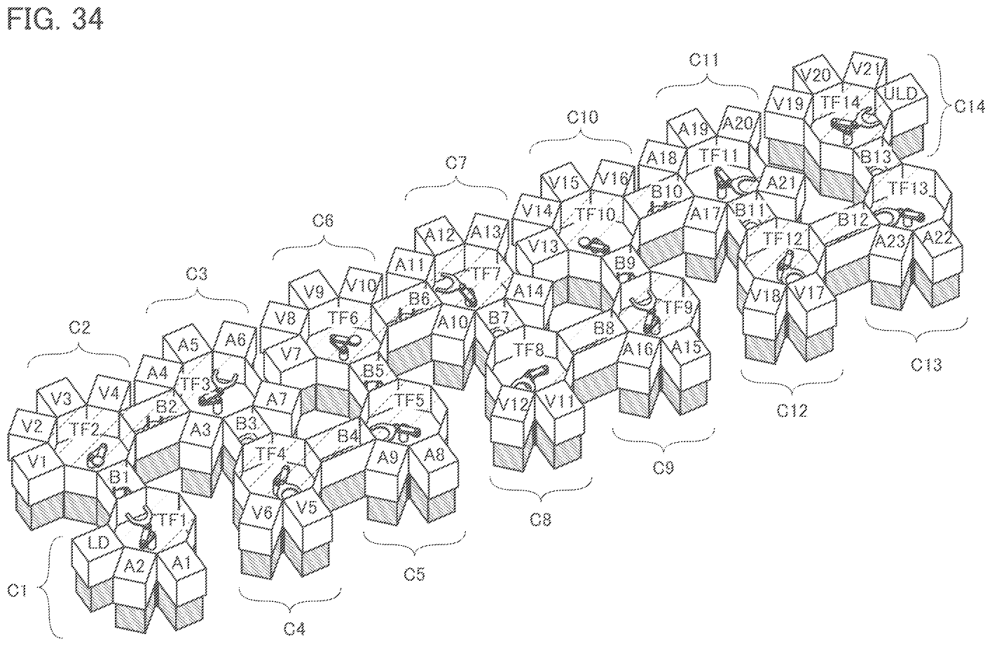

FIG. 34 illustrates an example of manufacturing equipment that can be used for the above-described steps from the formation of the EL film 112Rf up to the formation of the protective layer 121. The basic structure of the manufacturing equipment illustrated in FIG. 34 is similar to that of the manufacturing equipment illustrated in FIG. 1.

The cluster C1 to the cluster C14 are specifically described below. FIG. 34 is a schematic perspective view of the whole of the manufacturing equipment, where utilities, gate valves, and the like are not illustrated. In the drawing, the insides of the transfer chambers TF1 to TF14 and the loadlock chambers B1 to B13 are made visible for the sake of clarity.

### <Cluster C1>

The cluster C1 includes the load chamber LD and the normal-pressure process apparatuses A1 and A2. The normal-pressure process apparatus A1 can be a cleaning apparatus, and the normal-pressure process apparatus A2 can be a baking apparatus. In the cluster C1, a cleaning step prior to deposition of the EL film 112Rf is performed.

### <Cluster C2>

The cluster C2 includes vacuum process apparatuses V1 to V4. The vacuum process apparatuses V1 to V4 are an evaporation apparatus for forming the EL film 112Rf and a deposition apparatus for forming the protective film 125Rf (e.g., an evaporation apparatus or an ALD apparatus). For example, the vacuum process apparatus V1 can be an apparatus for forming an organic compound layer to be a light-emitting layer (R). The vacuum process apparatuses V2 and V3 can each be assigned to an apparatus for forming an organic compound layer such as an electron-injection layer, an electron-transport layer, a charge-generation layer, a hole-transport layer, or a hole-injection layer. Furthermore, the vacuum process apparatus V4 can be assigned to an apparatus for forming the protective film 125Rf.

### <Cluster C3>

The cluster C3 includes the normal-pressure process apparatuses A3 to A7. The normal-pressure process apparatuses A3 to A7 can be apparatuses used for a lithography step. For example, the normal-pressure process apparatus A3 is a resin (photoresist) application apparatus, the normal-pressure process apparatus A4 is a pre-baking apparatus, the normal-pressure process apparatus A5 is a light-exposure apparatus, the normal-pressure process apparatus A6 is a developing apparatus, the normal-pressure process apparatus A7 is a post-baking apparatus. Alternatively, the normal-pressure process apparatus A5 may be a nanoimprint apparatus.

### <Cluster C4>

The cluster C4 includes the vacuum process apparatuses V5 and V6. The vacuum process apparatus V5 can be a dry etching apparatus for forming the EL layer 112R. The vacuum process apparatus V6 can be an ashing apparatus for removing a resist mask.

### <Cluster C5>

The cluster C5 includes the normal-pressure process apparatuses A8 and A9. The normal-pressure process apparatus A8 can be a cleaning apparatus, and the normal-pressure process apparatus A9 can be a baking apparatus. In the cluster C5, a cleaning step prior to deposition of the EL film 112Gf is performed.

### <Cluster C6>

The cluster C6 includes the vacuum process apparatuses V7 to V10. The vacuum process apparatuses V7 to V10 are an evaporation apparatus for forming the EL film 112Gf and a deposition apparatus (e.g., sputtering apparatus) for forming the protective film 125Gf. For example, the vacuum process apparatus V7 can be an apparatus for forming an organic compound layer to be a light-emitting layer (G). The vacuum process apparatuses V8 and V9 can each be assigned to an apparatus for forming an organic compound layer such as an electron-injection layer, an electron-transport layer, a charge-generation layer, a hole-transport layer, or a hole-injection layer. Furthermore, the vacuum process apparatus V10 can be assigned to an apparatus for forming the protective film 125Gf.

### <Cluster C7>

The cluster C7 includes the normal-pressure process apparatuses A10 to A14. The normal-pressure process apparatuses A10 to A14 can be apparatuses used for a lithography step. The apparatuses can be assigned in a manner similar to those of the cluster C3.

### <Cluster C8>

The cluster C8 includes the vacuum process apparatuses V11 and V12. The vacuum process apparatus V11 can be a dry etching apparatus for forming the EL layer 112G. The vacuum process apparatus V12 can be an ashing apparatus for removing a resist mask.

### <Cluster C9>

The cluster C9 includes the normal-pressure process apparatuses A15 and A16. The normal-pressure process apparatus A15 can be a cleaning apparatus, and the normal-pressure process apparatus A16 can be a baking apparatus. In the cluster C9, a cleaning step prior to deposition of the EL film 112Bf is performed.

### <Cluster C10>

The cluster C10 includes the vacuum process apparatuses V13 to V16. The vacuum process apparatuses V13 to V16 are an evaporation apparatus for forming the EL film 112Bf and a deposition apparatus (e.g., sputtering apparatus) for forming the protective film 125Bf. For example, the vacuum process apparatus V13 can be an apparatus for forming an organic compound layer to be a light-emitting layer (G). The vacuum process apparatuses V14 and V15 can be assigned to apparatuses for formation of organic compound layers such as an electron-injection layer, an electron-transport layer, a charge-generation layer, a hole-transport layer, and a hole-injection layer. Furthermore, the vacuum process apparatus V16 can be assigned to an apparatus for forming the protective film 125Bf.

### <Cluster C11>

The cluster C11 includes the normal-pressure process apparatuses A17 to A21. The normal-pressure process apparatuses A17 to A21 can be apparatuses used for a lithography step. The apparatuses can be assigned in a manner similar to those of the cluster C3.

### <Cluster C12>

The cluster C12 includes vacuum process apparatuses V17 and V18. The vacuum process apparatus V17 can be a dry etching apparatus for forming the EL layer 112B. The vacuum process apparatus V18 can be an ashing apparatus for removing a resist mask.

### <Cluster C13>

The cluster C13 includes the normal-pressure process apparatuses A22 and A23. The normal-pressure process apparatus A22 can be a wet etching apparatus, and the normal-pressure process apparatus A23 can be a baking apparatus. In the cluster C9, etching steps of the protective layers 125R, 125G, and 125B are performed.

### <Cluster C14>

The cluster C14 includes the vacuum process apparatuses V19 to V21 and the unload chamber ULD. The vacuum process apparatus V19 can be assigned to an apparatus (e.g., an evaporation apparatus) for forming an organic compound layer such as an electron-injection layer, an electron-transport layer, a charge-generation layer, a hole-transport layer, or a hole-injection layer. Furthermore, the vacuum process apparatus V20 can be a deposition apparatus (e.g., a sputtering apparatus) for forming the common electrode 113. The vacuum process apparatus V21 can be a deposition apparatus (e.g., a sputtering apparatus) for forming the protective layer 121. Alternatively, another vacuum process apparatus V may be provided and a plurality of different deposition apparatuses (such as an evaporation apparatus or an ALD apparatus) are provided to form the common electrode 113 and the protective layer 121 so as to have stacked films.

Steps using the manufacturing equipment illustrated in FIG. 34, processing apparatuses, and components corresponding to the above-described manufacturing method are summarized in Table 1. Note that carrying of the substrate into and out of the loadlock chamber and the apparatuses are not described.

TABLE 1

| Step | | Processing | |
|---|---|---|---|
| No. | Step | apparatus | Component |
| 1 | Cleaning | A1 | |
| 2 | Baking | A2 | |
| 3 | Deposition of organic compound layer | V1 | 112Rf |
| 4 | Deposition of organic compound layer | V2 | |
| | (light-emitting layer) | | |
| 5 | Deposition of organic compound layer | V3 | |
| 6 | Deposition of protective film | V4 | 125Rf |
| 7 | Application of photoresist | A3 | |
| 8 | Pre-baking | A4 | |
| 9 | Light exposure | A5 | |
| 10 | Developing | A6 | |
| 11 | Post-baking | A7 | |
| 12 | Etching of protective film | V5 | 125R |
| 13 | Etching of organic compound layer | V5 | 112R |
| 14 | Ashing of resist mask | V6 | |
| 15 | Cleaning | A8 | |
| 16 | Baking | A9 | |
| 17 | Deposition of organic compound layer | V7 | 112Gf |
| 18 | Deposition of organic compound layer | V8 | |
| | (light-emitting layer) | | |
| 19 | Deposition of organic compound layer | V9 | |
| 20 | Deposition of protective film | V10 | 125Gf |
| 21 | Application of photoresist | A10 | |
| 22 | Pre-baking | A11 | |
| 23 | Light exposure | A12 | |
| 24 | Developing | A13 | |
| 25 | Post-baking | A14 | |
| 26 | Etching of protective film | V11 | 125Gf |
| 27 | Etching of organic compound layer | V11 | 112Gf |
| 28 | Ashing of resist mask | V12 | |
| 29 | Cleaning | A15 | |
| 30 | Baking | A16 | |
| 31 | Deposition of organic compound layer | V13 | 112Bf |
| 32 | Deposition of organic compound layer | V14 | |
| | (light-emitting layer) | | |
| 33 | Deposition of organic compound layer | V15 | |
| 34 | Deposition of protective film | V16 | 125Bf |
| 35 | Application of photoresist | A17 | |
| 36 | Pre-baking | A18 | |
| 37 | Light exposure | A19 | |
| 38 | Developing | A20 | |
| 39 | Post-baking | A21 | |
| 40 | Etching of protective film | V17 | 125Bf |
| 41 | Etching of organic compound layer | V17 | 112Bf |
| 42 | Ashing of resist mask | V18 | |
| 43 | Etching (removal) of protective film | A22 | |
| 44 | Baking | A23 | |
| 45 | Deposition of organic compound layer | V19 | |
| 46 | Deposition of common electrode | V20 | 113 |
| 47 | Deposition of protective film | V21 | 121 |

The manufacturing equipment of one embodiment of the present invention has a function of performing Step No. 1 to Step No. 47 in Table 1 automatically.

### Example 2 of Manufacturing Equipment

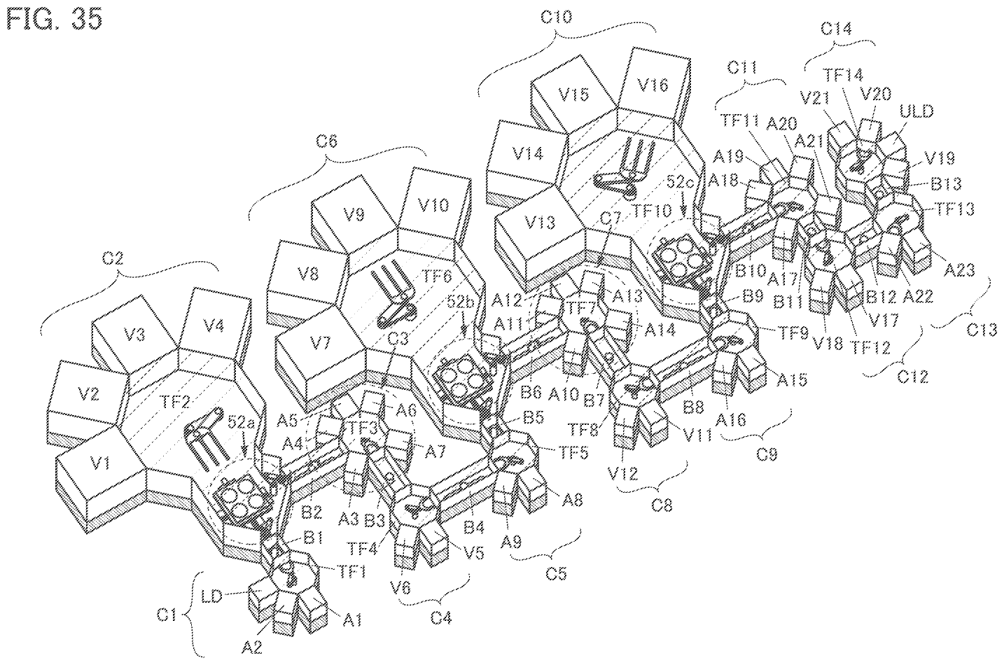

FIG. 35 illustrates an example of manufacturing equipment that is different from Example 1 of manufacturing equipment. The basic structure of the manufacturing equipment in FIG. 35 is similar to that of the manufacturing equipment illustrated in FIG. 34.

The cluster C1 to the cluster C14 are specifically described below. FIG. 35 is a schematic perspective view of the whole of the manufacturing equipment, where utilities, gate valves, and the like are not illustrated. In the drawing, the insides of the transfer chambers TF1 to TF14 and the loadlock chambers B1 to B13 are made visible for the sake of clarity.

### <Cluster C1>

The cluster C1 includes the load chamber LD and the normal-pressure process apparatuses A1 and A2. The normal-pressure process apparatus A1 can be a cleaning apparatus and the normal-pressure process apparatus A2 can be a baking apparatus. In the cluster C1, a cleaning step prior to deposition of the EL film 112Rf is performed.

### <Cluster C2>

The cluster C2 includes the substrate transfer device 52a and the vacuum process apparatuses V1 to V4. The vacuum process apparatuses V1 to V4 are an evaporation apparatus for forming the EL film 112Rf and a deposition apparatus for forming the protective film 125Rf (e.g., an evaporation apparatus or an ALD apparatus). For example, the vacuum process apparatus V1 can be an apparatus for forming an organic compound layer to be a light-emitting layer (R). The vacuum process apparatuses V2 and V3 can be assigned to apparatuses for formation of organic compound layers such as an electron-injection layer, an electron-transport layer, a charge-generation layer, a hole-transport layer, and a hole-injection layer. Furthermore, the vacuum process apparatus V4 can be assigned to an apparatus for forming the protective film 125Rf.

### <Cluster C3>

The cluster C3 includes the normal-pressure process apparatuses A3 to A7. The normal-pressure process apparatuses A3 to A7 can be apparatuses used for a lithography step. For example, the normal-pressure process apparatus A3 can be a resin (photoresist) application apparatus, the normal-pressure process apparatus A4 can be a pre-baking apparatus, the normal-pressure process apparatus A5 can be a light-exposure apparatus, the normal-pressure process apparatus A6 can be a developing apparatus, the normal-pressure process apparatus A7 can be a post-baking apparatus. Alternatively, the normal-pressure process apparatus A5 may be a nanoimprint apparatus.

### <Cluster C4>

The cluster C4 includes the vacuum process apparatuses V5 and V6. The vacuum process apparatus V5 can be a dry etching apparatus for forming the EL layer 112R. The vacuum process apparatus V6 can be an ashing apparatus for removing a resist mask.

### <Cluster C5>

The cluster C5 includes the normal-pressure process apparatuses A8 and A9. The normal-pressure process apparatus A8 can be a cleaning apparatus, and the normal-pressure process apparatus A9 can be a baking apparatus. In the cluster C5, a cleaning step prior to deposition of the EL film 112Gf is performed.

### <Cluster C6>

The cluster C6 includes the substrate transfer device 52b and the vacuum process apparatuses V7 to V10. The vacuum process apparatus V7 to V10 are an evaporation apparatus for forming the EL film 112Gf and a deposition apparatus (e.g., sputtering apparatus) for forming the protective film 125Gf. For example, the vacuum process apparatus V7 can be an apparatus for forming an organic compound layer to be a light-emitting layer (G). The vacuum process apparatuses V8 and V9 can be assigned to apparatuses for formation of organic compound layers such as an electron-injection layer, an electron-transport layer, a charge-generation layer, a hole-transport layer, and a hole-injection layer. Furthermore, the vacuum process apparatus V10 can be assigned to an apparatus for forming the protective film 125Gf.

### <Cluster C7>

The cluster C7 includes the normal-pressure process apparatus A10 to A14. The normal-pressure process apparatuses A10 to A14 can be apparatuses used for a lithography step. The apparatuses can be assigned in a manner similar to those of the cluster C3.

### <Cluster C8>

The cluster C8 includes the vacuum process apparatuses V11 and V12. The vacuum process apparatus V11 can be a dry etching apparatus for forming the EL layer 112G. The vacuum process apparatus V12 can be an ashing apparatus for removing a resist mask.

### <Cluster C9>

The cluster C9 includes the normal-pressure process apparatuses A15 and A16. The normal-pressure process apparatus A15 can be a cleaning apparatus, and the normal-pressure process apparatus A16 can be a baking apparatus. In the cluster C9, a cleaning step prior to deposition of the EL film 112Bf is performed.

### <Cluster C10>

The cluster C10 includes the substrate transfer device 52c and the vacuum process apparatuses V13 to V16. The vacuum process apparatus V13 to V16 are an evaporation apparatus for forming the EL film 112Bf and a deposition apparatus (e.g., sputtering apparatus) for forming the protective film 125Bf. For example, the vacuum process apparatus V13 can be an apparatus for forming an organic compound layer to be a light-emitting layer (G). The vacuum process apparatuses V14 and V15 can be assigned to apparatuses for formation of organic compound layers such as an electron-injection layer, an electron-transport layer, a charge-generation layer, a hole-transport layer, and a hole-injection layer. Furthermore, the vacuum process apparatus V16 can be assigned to an apparatus for forming the protective film 125Bf.

### <Cluster C11>

The cluster C11 includes the normal-pressure process apparatuses A17 to A21. The normal-pressure process apparatuses A17 to A21 can be apparatuses used for a lithography step. The apparatuses can be assigned in a manner similar to those of the cluster C3.

### <Cluster C12>

The cluster C12 includes the vacuum process apparatuses V17 and V18. The vacuum process apparatus V17 can be a dry etching apparatus for forming the EL layer 112B. The vacuum process apparatus V18 can be an ashing apparatus for removing a resist mask.

### <Cluster C13>

The cluster C13 includes the normal-pressure process apparatuses A22 and A23. The normal-pressure process apparatus A22 can be a wet etching apparatus, and the normal-pressure process apparatus A23 can be a baking apparatus. In the cluster C9, etching steps of the protective layers 125R, 125G, and 125B are performed.

### <Cluster C14>

The cluster C14 the includes vacuum process apparatuses V19 to V21 and the unload chamber ULD. The vacuum process apparatus V19 can be assigned to apparatuses (e.g., an evaporation apparatus) for formation of organic compound layers such as an electron-injection layer, an electron-transport layer, a charge-generation layer, a hole-transport layer, and a hole-injection layer. Furthermore, the vacuum process apparatus V20 can be a deposition apparatus (e.g., a sputtering apparatus) for forming the common electrode 113. The vacuum process apparatus V21 can be a deposition apparatus (e.g., a sputtering apparatus) for forming the protective layer 121. Alternatively, another vacuum process apparatus V may be provided and a plurality of different deposition apparatuses (such as an evaporation apparatus or an ALD apparatus) are provided to form the common electrode 113 and the protective layer 121 so as to have stacked films.

Steps using the manufacturing equipment illustrated in FIG. 22, processing apparatuses, and components corresponding to the above-described manufacturing method are summarized in Table 2. Note that carrying of the substrate into and out of the loadlock chamber and the apparatuses are not described.

TABLE 2

| Step | | Processing | |
|---|---|---|---|
| No. | Step | apparatus | Component |
| 1 | Cleaning | A1 | |
| 2 | Baking | A2 | |
| 3 | Transfer substrate | 52a | |
| 4 | Deposition of organic compound layer | V1 | 112Rf |
| 5 | Deposition of organic compound layer | V2 | |
| | (light-emitting layer) | | |
| 6 | Deposition of organic compound layer | V3 | |
| 7 | Deposition of protective film | V4 | 125Rf |
| 8 | Transfer substrate | 52a | |
| 9 | Application of photoresist | A3 | |
| 10 | Pre-baking | A4 | |
| 11 | Light exposure | A5 | |
| 12 | Developing | A6 | |
| 13 | Post-baking | A7 | |
| 14 | Etching of protective film | V5 | 125R |
| 15 | Etching of organic compound layer | V5 | 112R |
| 16 | Ashing of resist mask | V6 | |
| 17 | Cleaning | A8 | |
| 18 | Baking | A9 | |
| 19 | Transfer substrate | 52b | |
| 20 | Deposition of organic compound layer | V7 | 112Gf |
| 21 | Deposition of organic compound layer | V8 | |
| | (light-emitting layer) | | |
| 22 | Deposition of organic compound layer | V9 | |
| 23 | Deposition of protective film | V10 | 125Gf |
| 24 | Transfer substrate | 52b | |
| 25 | Application of photoresist | A10 | |
| 26 | Pre-baking | A11 | |
| 27 | Light exposure | A12 | |
| 28 | Developing | A13 | |
| 29 | Post-baking | A14 | |
| 30 | Etching of protective film | V11 | 125Gf |
| 31 | Etching of organic compound layer | V11 | 112Gf |
| 32 | Ashing of resist mask | V12 | |
| 33 | Cleaning | A15 | |
| 34 | Baking | A16 | |
| 35 | Transfer substrate | 52c | |
| 36 | Deposition of organic compound layer | V13 | 112Bf |
| 37 | Deposition of organic compound layer | V14 | |
| | (light-emitting layer) | | |
| 38 | Deposition of organic compound layer | V15 | |
| 39 | Deposition of protective film | V16 | 125Bf |
| 40 | Transfer substrate | 52c | |
| 41 | Application of photoresist | A17 | |
| 42 | Pre-baking | A18 | |
| 43 | Light exposure | A19 | |
| 44 | Developing | A20 | |
| 45 | Post-baking | A21 | |
| 46 | Etching of protective film | V17 | 125Bf |
| 47 | Etching of organic compound layer | V17 | 112Bf |
| 48 | Ashing of resist mask | V18 | |
| 49 | Etching (removal) of protective film | A22 | |
| 50 | Baking | A23 | |
| 51 | Deposition of organic compound layer | V19 | |
| 52 | Deposition of common electrode | V20 | 113 |
| 53 | Deposition of protective film | V21 | 121 |

The manufacturing equipment of one embodiment of the present invention has a function of performing Step No. 1 to Step No. 53 in Table 2 automatically.

This embodiment can be implemented in an appropriate combination with the structures described in the other embodiments.

### REFERENCE NUMERALS

A10: normal-pressure process apparatus, A14: normal-pressure process apparatus, A15: normal-pressure process apparatus, A16: normal-pressure process apparatus, A17: normal-pressure process apparatus, A21: normal-pressure process apparatus, A22: normal-pressure process apparatus, A23: normal-pressure process apparatus, B10: loadlock chamber, B11: loadlock chamber, B12: loadlock chamber, B13: loadlock chamber, C10: cluster, C11: cluster, C12: cluster, C13: cluster, C14: cluster, LD: load chamber, TF: transfer chamber, TF10: transfer chamber, TF11: transfer chamber, TF12: transfer chamber, TF13: transfer chamber, TF14: transfer chamber, TF46: transfer chamber, TF810: transfer chamber, ULD: unload chamber, V10: vacuum process apparatus, V11: vacuum process apparatus, V12: vacuum process apparatus, V13: vacuum process apparatus, V14: vacuum process apparatus, V15: vacuum process apparatus, V16: vacuum process apparatus, V17: vacuum process apparatus, V18: vacuum process apparatus, V19: vacuum process apparatus, V20: vacuum process apparatus, V21: vacuum process apparatus, VP: vacuum pump, 30: deposition apparatus, 31: deposition material supply unit, 32: mask jig, 33: substrate alignment unit, 35: opening portion, 40: deposition apparatus, 41: rail, 42: deposition material supply unit, 43: cooling plate, 44: inlet port, 45: outlet port, 46: sealant, 52a: substrate transfer device, 52b: substrate transfer device, 52c: substrate transfer device, 60a: substrate, 60b: substrate, 60: substrate, 61: mask jig, 62: depression portion, 63: opening portion, 64: depression portion, 70a: carrying device, 70b: carrying device, 70c: carrying device, 70d: carrying device, 70e: carrying device, 70f: carrying device, 70g: carrying device, 70h: carrying device, 70i: carrying device, 70j: carrying device, 70k: carrying device, 71a: carrying device, 71b: carrying device, 71c: carrying device, 72a: carrying device, 72b: carrying device, 72c: carrying device, 72d: carrying device, 72e: carrying device, 72f: carrying device, 80a: stage, 80b: stage, 80c: stage, 80d: stage, 80e: stage, 80f: stage, 81a: stage, 81b: stage, 81c: stage, 81d: stage, 81e: stage, 81f: stage, 82: pin, 83a: stage, 83b: stage, 83c: stage, 84x: X-axis moving mechanism, 84y: Y-axis moving mechanism, 85: pusher pin, 86: camera, 87: rail, 91: lifting mechanism, 92: arm, 93: hand portion, 94: lifting mechanism, 95: arm, 96: substrate fixing portion, 97: rotation mechanism, 98: substrate rotation mechanism, 100: display device, 110B: light-emitting element, 110G: light-emitting element, 110R: light-emitting element, 111: pixel electrode, 112B: EL layer, 112Bf: EL film, 112G: EL layer, 112Gf: EL film, 112R: EL layer, 112Rf: EL film, 112W: EL layer, 113: common electrode, 114B: coloring layer, 114G: coloring layer, 114R: coloring layer, 115: transistor, 116: transistor, 117: transistor, 121: protective layer, 125B: protective layer, 125Bf: protective film, 125G: protective layer, 125Gf: protective film, 125R: protective layer, 125Rf: protective film, 131: insulating layer, 143a: resist mask, 143b: resist mask, 143c: resist mask,

1. A manufacturing equipment of a light-emitting device, comprising:
a first cluster to an eleventh cluster and a first loadlock chamber to a tenth loadlock chamber,
wherein the first cluster is connected to the second cluster through the first loadlock chamber,
wherein the second cluster is connected to the third cluster through the second loadlock chamber,
wherein the third cluster is connected to the fourth cluster through the third loadlock chamber,
wherein the fourth cluster is connected to the fifth cluster through the fourth loadlock chamber,
wherein the fifth cluster is connected to the sixth cluster through the fifth loadlock chamber,
wherein the sixth cluster is connected to the seventh cluster through the sixth loadlock chamber,
wherein the seventh cluster is connected to the eighth cluster through the seventh loadlock chamber,
wherein the eighth cluster is connected to the ninth cluster through the eighth loadlock chamber,
wherein the ninth cluster is connected to the tenth cluster through the ninth loadlock chamber,
wherein the tenth cluster is connected to the eleventh cluster through the tenth loadlock chamber,
wherein each of the first cluster, the third cluster, the fourth cluster, the sixth cluster, the seventh cluster, the ninth cluster and the eleventh cluster is independently connected to a vacuum pump to reduce each pressure,
wherein each of atmospheres in the second cluster, the fifth cluster, the eighth cluster and the tenth cluster is independently connected to an inert gas atmosphere,
wherein each of the first cluster, the fourth cluster and the seventh cluster independently comprises a first carrying device and a first plurality of deposition apparatuses,
wherein each of the third cluster, the sixth cluster and the ninth cluster independently comprises a second carrying device, an etching apparatus and an ashing apparatus,
wherein each of the second cluster, the fifth cluster and the eighth cluster independently comprises a third carrying device and a plurality of apparatuses to perform lithography,
wherein the tenth cluster comprises a fourth carrying device and an etching apparatus,
wherein the eleventh cluster comprises a fifth carrying device and a second plurality of deposition apparatuses,
wherein the first carrying device comprises a substrate fixing portion, and
wherein the first carrying device has a mechanism of rotating the substrate fixing portion to reverse a substrate.

2-14. (canceled)

15. The manufacturing equipment of a light-emitting device according to claim 1, further comprising a twelfth cluster and an eleventh loadlock chamber,
wherein the twelfth cluster is connected to the first cluster through the eleventh loadlock chamber,
wherein an atmosphere in the twelfth cluster is connected to an inert gas atmosphere, and
wherein the twelfth cluster comprises a cleaning apparatus and a baking apparatus.

16. The manufacturing equipment of a light-emitting device according to claim 15,
wherein the twelfth cluster comprises a load chamber, and
wherein the eleventh cluster comprises an unload chamber.

17. The manufacturing equipment of a light-emitting device, according to claim 1, further comprising a thirteenth cluster, a fourteenth cluster, a twelfth loadlock chamber and a thirteenth loadlock chamber,
wherein the thirteenth cluster is connected to the third cluster through the third loadlock chamber,
wherein the thirteenth cluster is connected to the fourth cluster through the twelfth loadlock chamber,
wherein the fourteenth cluster is connected to the sixth cluster through the sixth loadlock chamber,
wherein the fourteenth cluster is connected to the seventh cluster through the thirteenth loadlock chamber,
wherein each of atmospheres in the thirteenth cluster and the fourteenth cluster is independently connected to an inert gas atmosphere, and
wherein each of the thirteenth cluster and the fourteenth cluster independently comprises a cleaning apparatus and a baking apparatus.

18. The manufacturing equipment of a light-emitting device according to claim 1, wherein each of the first cluster, the fourth cluster and the seventh cluster independently comprises one or more of an evaporation apparatus, a sputtering apparatus, a chemical vapor deposition apparatus and an atomic layer deposition apparatus.

19. The manufacturing equipment of a light-emitting device according to claim 1, wherein each of the third cluster, the sixth cluster and the ninth cluster comprises a dry etching apparatus.

20. The manufacturing equipment of a light-emitting device according to claim 1, wherein the tenth cluster comprises a wet etching apparatus.

21. The manufacturing equipment of a light-emitting device according to claim 1, wherein each of the second cluster, the fifth cluster and the eighth cluster independently comprises an application apparatus, a light-exposure apparatus, a developing apparatus and a baking apparatus in the plurality of apparatuses to perform lithography.

22. The manufacturing equipment of a light-emitting device according to claim 1, wherein each of the second cluster, the fifth cluster and the eighth cluster independently further comprises an application apparatus and a nanoimprint apparatus in the plurality of apparatuses to perform lithography.

23. The manufacturing equipment of a light-emitting device according to claim 1, wherein the manufacturing equipment is configured to manufacture a light-emitting device on a silicon wafer.

24. The manufacturing equipment of a light-emitting device according to claim 1,
wherein each of the first plurality of deposition apparatuses comprises an alignment mechanism and a mask jig, and
wherein the alignment mechanism has a mechanism of attaching a substrate to the mask jig.

25. A manufacturing equipment of a light-emitting device, comprising:
a first cluster to an eleventh cluster and a first loadlock chamber to a tenth loadlock chamber,
wherein the first cluster is connected to the second cluster through the first loadlock chamber,
wherein the second cluster is connected to the third cluster through the second loadlock chamber,
wherein the third cluster is connected to the fourth cluster through the third loadlock chamber,
wherein the fourth cluster is connected to the fifth cluster through the fourth loadlock chamber,
wherein the fifth cluster is connected to the sixth cluster through the fifth loadlock chamber,
wherein the sixth cluster is connected to the seventh cluster through the sixth loadlock chamber,
wherein the seventh cluster is connected to the eighth cluster through the seventh loadlock chamber,
wherein the eighth cluster is connected to the ninth cluster through the eighth loadlock chamber,
wherein the ninth cluster is connected to the tenth cluster through the ninth loadlock chamber,
wherein the tenth cluster is connected to the eleventh cluster through the tenth loadlock chamber,
wherein the first cluster, the third cluster, the fourth cluster, the sixth cluster, the seventh cluster, the ninth cluster and the eleventh cluster is independently connected to a vacuum pump to reduce each pressure,
wherein each of atmospheres in the second cluster, the fifth cluster, the eighth cluster and the tenth cluster is connected to inert gas atmospheres,
wherein each of the first cluster, the fourth cluster and the seventh cluster independently comprises a first carrying device, a substrate transfer device and a first plurality of deposition apparatuses,
wherein each of the third cluster, the sixth cluster and the ninth cluster independently comprises a second carrying device, an etching apparatus and an ashing apparatus,
wherein each of the second cluster, the fifth cluster and the eighth cluster independently comprises a third carrying device and a plurality of apparatuses to perform lithography,
wherein the tenth cluster comprises a fourth carrying device and an etching apparatus,
wherein the eleventh cluster comprises a fifth carrying device and a second plurality of deposition apparatuses, and in each of the first cluster, the fourth cluster and the seventh cluster:
wherein the substrate transfer device comprises a stage, a sixth carrying device and a seventh carrying device;
wherein the stage has a place to place a mask jig on the stage;
wherein the first carrying device is configure to carry the mask jig;
wherein the sixth carrying device has a mechanism of reversing a substrate to be mounted and a mechanism of mounting the substrate on the mask jig; and
wherein the seventh carrying device has a mechanism of taking out the substrate from being mounted on the mask jig and a mechanism of reversing the substrate.

26. The manufacturing equipment of a light-emitting device according to claim 25,
wherein each of the first cluster, the fourth cluster and the seventh cluster has an alignment mechanism,
in each of the first cluster, the fourth cluster and the seventh cluster:
wherein the substrate transfer device comprises a camera;
wherein the sixth carrying device has a substrate rotation mechanism; and
wherein the alignment mechanism is configured to adjust a position of the substrate by using the camera and the substrate rotation mechanism in order to mount the substrate on the mask jig.

27. The manufacturing equipment of a light-emitting device according to claim 26, wherein the mask jig is configured to mount a plurality of substrates.

28. The manufacturing equipment of a light-emitting device according to claim 25, further comprising a twelfth cluster and an eleventh loadlock chamber,
wherein the twelfth cluster is connected to the first cluster through the eleventh loadlock chamber,
wherein an atmosphere in the twelfth cluster is connected to an inert gas atmosphere, and
wherein the twelfth cluster comprises a cleaning apparatus and a baking apparatus.

29. The manufacturing equipment of a light-emitting device according to claim 28,
wherein the twelfth cluster comprises a load chamber, and
wherein the eleventh cluster comprises an unload chamber.

30. The manufacturing equipment of a light-emitting device, according to claim 25, further comprising a thirteenth cluster, a fourteenth cluster, a twelfth loadlock chamber and a thirteenth loadlock chamber,
wherein the thirteenth cluster is connected to the third cluster through the third loadlock chamber,
wherein the thirteenth cluster is connected to the fourth cluster through the twelfth loadlock chamber,
wherein the fourteenth cluster is connected to the sixth cluster through the sixth loadlock chamber,
wherein the fourteenth cluster is connected to the seventh cluster through the thirteenth loadlock chamber,
wherein each of atmospheres in the thirteenth cluster and the fourteenth cluster is independently connected to an inert gas atmosphere, and
wherein each of the thirteenth cluster and the fourteenth cluster independently comprises a cleaning apparatus and a baking apparatus.

31. The manufacturing equipment of a light-emitting device according to claim 25, wherein each of the first cluster, the fourth cluster and the seventh cluster independently comprises one or more of an evaporation apparatus, a sputtering apparatus, a chemical vapor deposition apparatus and an atomic layer deposition apparatus.

32. The manufacturing equipment of a light-emitting device according to claim 25, wherein each of the third cluster, the sixth cluster and the ninth cluster comprises a dry etching apparatus.

33. The manufacturing equipment of a light-emitting device according to claim 25, wherein the tenth cluster comprises a wet etching apparatus.

34. The manufacturing equipment of a light-emitting device according to claim 25, wherein each of the second cluster, the fifth cluster and the eighth cluster independently comprises an application apparatus, a light-exposure apparatus, a developing apparatus and a baking apparatus in the plurality of apparatuses to perform lithography.

35. The manufacturing equipment of a light-emitting device according to claim 25, wherein each of the second cluster, the fifth cluster and the eighth cluster independently further comprises an application apparatus and a nanoimprint apparatus in the plurality of apparatuses to perform lithography.

36. The manufacturing equipment of a light-emitting device according to claim 25, wherein the manufacturing equipment is configured to manufacture a light-emitting device on a silicon wafer.

37. The manufacturing equipment of a light-emitting device according to claim 25,
wherein each of the first plurality of deposition apparatuses comprises an alignment mechanism and a mask jig, and
wherein the alignment mechanism has a mechanism of attaching a substrate to the mask jig.
